(19) United States
(12) Patent Application Publication
(10) Pub. No.: US 2022/0077099 A1
(43) Pub. Date: Mar. 10, 2022

(54) COMPOSITION FOR CONDUCTIVE ADHESIVE, SEMICONDUCTOR PACKAGE COMPRISING CURED PRODUCT THEREOF, AND METHOD OF MANUFACTURING SEMICONDUCTOR PACKAGE USING THE SAME

(71) Applicant: ELECTRONICS AND TELECOMMUNICATIONS RESEARCH INSTITUTE, Daejeon (KR)

(72) Inventors: Gwang-Mun CHOI, Daejeon (KR); Yong-Sung EOM, Daejeon (KR); Kwang-Seong CHOI, Daejeon (KR); Jiho JOO, Daejeon (KR); Ki-Seok JANG, Daejeon (KR); Chanmi LEE, Daejeon (KR)

(73) Assignee: ELECTRONICS AND TELECOMMUNICATIONS RESEARCH INSTITUTE, Daejeon (KR)

(21) Appl. No.: 17/467,557

(22) Filed: Sep. 7, 2021

(30) Foreign Application Priority Data
Sep. 9, 2020 (KR) 10-2020-0115437
Aug. 3, 2021 (KR) 10-2021-0101819

(51) Int. Cl. H01L 23/00; C09J 9/02; C09J 5/00; C09J 7/30; C09J 7/10

(52) U.S. Cl. CPC H01L 24/29; H01L 2924/01015; C09J 5/00; C09J 7/30; C09J 7/10; H01L 24/83; C09J 2463/00; C09J 2301/416; C09J 2203/326; H01L 2224/2969; H01L 2224/29811; H01L 2224/29847; H01L 2224/29839; H01L 2224/29813; H01L 2224/29809; H01L 2224/29816; H01L 2224/29801; H01L 2224/2982; H01L 2224/29805; H01L 2224/29817; H01L 2224/29818; H01L 2224/29824; H01L 2224/29844; H01L 2224/29838; H01L 2224/29855; H01L 2224/83851; H01L 2924/0105; H01L 2924/01029; H01L 2924/01047; H01L 2924/01083; H01L 2924/01049; H01L 2924/01082; H01L 2924/01048; H01L 2924/01051; H01L 2924/01031; H01L 2924/01033; H01L 2924/01032; H01L 2924/0103; H01L 2924/01013; H01L 2924/01079; H01L 2924/01014; H01L 2924/01028; C09J 9/02

(57) ABSTRACT

Provided is a composition for conductive adhesive. The composition for conductive adhesive includes a heterocyclic compound containing oxygen and including at least one of an epoxy group or oxetane group, a reductive curing agent including an amine group and a carboxyl group, and a photoinitiator, wherein a mixture ratio of the heterocyclic compound and the reductive curing agent satisfies Conditional Expression 1 below.

0.5≤(b+c)/a≤1.5, a>0, b≥0, c>0 [Conditional Expression 1]
where ‘a’ denotes a mole number of a heterocycle in the heterocyclic compound, ‘b’ denotes a mole number of hydrogen bonded to a nitrogen atom of the amine group included in the reductive curing agent, and ‘c’ denotes a mole number of the carboxyl group.

### CROSS-REFERENCE TO RELATED APPLICATIONS

This U.S. non-provisional patent application claims priority under 35 U.S.C. § 119 of Korean Patent Application Nos. 10-2020-0115437, filed on Sep. 9, 2020, and 10-2021-0101819, filed on Aug. 3, 2021, the entire contents of which are hereby incorporated by reference.

### BACKGROUND

The present disclosure herein relates to a composition for conductive adhesive which may be initiated by light and heat, a semiconductor package including a cured product thereof, and a method of manufacturing a semiconductor package using the same.

A typical conductive adhesive used to electrically and mechanically bond a semiconductor chip and a substrate typically includes solder having conductive particles and an insulating resin composition having thermosetting properties. For example, as a temperature increases, solder particles included in a conductive adhesive are melted and fused with each other so as to provide an electrical connection by being wet between an electrode of a substrate and a semiconductor chip, and an insulating resin squeezed out to a periphery is cured so as to protect a bonding portion. However, in the case of a typical conductive adhesive, it is difficult to avoid a heating bonding process due to a simple action mechanism by heat, and a pot life is short, and, thus, application of a new bonding process and imparting various functionalities by using the new bonding process are limited.

### SUMMARY

The present disclosure provides a composition for conductive adhesive having improved metal oxide film removal efficiency and pot life characteristic.

The present disclosure also provides a semiconductor package including a cured product of a composition for conductive adhesive having improved metal oxide film removal efficiency and pot life characteristic.

The present disclosure also provides a method of manufacturing a semiconductor package using a composition for conductive adhesive having improved metal oxide film removal efficiency and pot life characteristic.

An embodiment of the inventive concept provides a composition for conductive adhesive, including: a heterocyclic compound containing oxygen, the heterocyclic compound including at least one of an epoxy group or oxetane group; a reductive curing agent including an amine group and a carboxyl group; and a photoinitiator, wherein a mixture ratio of the heterocyclic compound and the reductive curing agent satisfies Conditional Expression 1 below.

0.5≤(b+c)/a≤1.5, a>0, b≥0, c>0 [Conditional Expression 1]

where ‘a’ denotes a mole number of a heterocycle in the heterocyclic compound, ‘b’ denotes a mole number of hydrogen bonded to a nitrogen atom of the amine group included in the reductive curing agent, and ‘c’ denotes a mole number of the carboxyl group.

In an embodiment, the heterocyclic compound may include at least one of bisphenol-A type epoxy resin, bisphenol-F type epoxy resin, novolac epoxy resin, hydrogenated bisphenol-A type epoxy resin, octylene oxide, p-butyl phenol glycidyl ether, butyl glycidyl ether, cresyl glycidyl ether, styrene oxide, allyl glycidyl ether, phenyl glycidyl ether, butadiene dioxide, divinylbenzene dioxide, diglycidyl ether, butanediol diglycidyl ether, limonene dioxide, vinylcyclohexene dioxide, diethylene glycol diglycidyl ether, 4-vinylcyclohexene dioxide, cyclohexene vinyl monoxide, (3,4-epoxycyclohexyl)methyl 3,4-epoxycyclohexylcarboxylate, 3,4-epoxycyclohexylmethyl methacrylate, 3,4-epoxycyclohexanecarboxylate, 2-(3,4-epoxycyclohexyl)-1,3-dioxolane, bis(3,4-epoxycyclohexylmethyl)adipate, 3-methyloxetane, 2-methyloxetane, 3-oxetanol, 2-methyleneoxetane, 3-methyl-3-hydroxymethyloxetane, 3-ethyl-3-hydroxymethyloxetane, 3,3-oxetanedimethanethiol, 2-ethylhexyloxetane, 4-(3-methyloxetan-3-yl)benzonitrile, N-(2,2-dimethylpropyl)-3-methyl-3-oxetanemethanamine, N-(1,2-dimethylbutyl)-3-methyl-3-oxetanemethanamine, xylene bis oxetane, 3-ethyl-3[{(3-ethyloxetan-3-yl)methoxy}methyl]oxetane, (3-ethyloxetan-3-yl)methyl methacrylate, 4-[(3-ethyloxetan-3-yl)methoxy]butan-1-ol, or combinations thereof.

In an embodiment, the reductive curing agent may include at least one of alpha(α)-amino acid, beta(β)-amino acid, gamma(γ)-amino acid, delta(δ)-amino acid, anthranilic acid, 3-aminobenzoic acid, para-aminobenzoic acid, or combinations thereof. For example, the reductive curing agent may include at least one of glycine, alanine, valine, leucine, isoleucine, lysine, arginine, histidine, aspartic acid, asparagine, glutamine, glutamic acid, phenylalanine, tyrosine, tryptophan, cysteine, methionine, serine, ornithine, 3-phenylserine, threonine, L-dopa, norleucine, penicillamine, sarcosine, proline, hydroxyproline, 3-hydroxyproline, 3,4-dihydroproline, pipecolic acid, β-alanine, 3-aminobutyric acid, isoserine, 3-aminoisobutyric acid, 3-amino-2-phenylpropionic acid, 3-amino-5-methylhexanoic acid, 3-amino-4-phenylbutyric acid, 3-amino-4-hydroxybutyric acid, 3-amino-4-hydroxypentanoic acid, 3-amino-4-methylpentanoic acid, 3-amino-3-phenylpropionic acid, pyrrolidine-3-carboxylic acid, γ-aminobutyric acid, 4-amino-3-hydroxybutyric acid, 3-pyrrolidine-2-yl-propionic acid, 3-aminocyclohexanecarboxylic acid, 4-guanidinobutyric acid, 4-aminobenzoic acid, 3-aminobenzoic acid, 2-aminobenzoic acid, 3,5-diaminobenzoic acid, 4-aminosalicylic acid, 5-aminosalicylic acid, 3-aminoisonicotinic acid, 4-aminonicotinic acid, 5-aminonicotinic acid, 2-aminonicotinic acid, 6-aminonicotinic acid, 2-aminoisonicotinic acid, 6-aminopicolinic acid, or combinations thereof.

In an embodiment, the photoinitiator may be included in an amount of about 0.1 to about 10 parts by weight based on 100 parts by weight of the heterocyclic compound.

In an embodiment, the composition for conductive adhesive may further include at least one of: an amine-based curing agent including an amine group; an acid anhydride-based curing agent including an acid anhydride group; or a reducing agent including a carboxyl group, wherein a mixture ratio of the amine-based curing agent, the acid anhydride-based curing agent, and the reducing agent may satisfy Conditional Expression 2 below.

0.5≤(b+c+d+e+f)/a≤1.5, (b+c)≥(d+e+f), a>0, b≥0, c>0, d≥0, e≥0, f≥0, d+e+f≠0 [Conditional Expression 2]

where ‘a’ denotes a mole number of a heterocycle in the heterocyclic compound, ‘b’ denotes a mole number of hydrogen bonded to a nitrogen atom of the amine group included in the reductive curing agent, ‘c’ denotes a mole number of the carboxyl group included in the reductive curing agent, ‘d’ denotes a mole number of hydrogen bonded to a nitrogen atom of the amine group included in the amine-based curing agent, ‘e’ denotes a mole number of the acid anhydride group included in the acid anhydride-based curing agent, and ‘f’ denotes a mole number of the carboxyl group included in the reducing agent.

In an embodiment, the amine-based curing agent may include at least one of diethylenetriamine, triethylenediamine, triethylenetetramine, tetraethylenepentamine, diethylaminopropyleneamine, aminoethylpiperazine, menthane diamine, isophorone diamine, methaphenilene diamine, diaminodiphenylmethane, diaminodiphenylsulfone, 2-methyl-4-nitroaniline, dicyandiamide, 2-methylimidazole, 2-ethyl-4-methylimidazole, 2,4-dimethylimidazole, 2-phenylimidazole, 2-phenyl-4-methylimidazole, 1-cyanoethyl-2-undecylimidazolium trimellitate, epoxyimidazole adduct, or combinations thereof.

In an embodiment, the acid anhydride-based curing agent may include at least one of phthalic anhydride, trimellitic anhydride, pyromellitic dianhydride, benzophenonetetracarboxylic dianhydride, maleic anhydride, tetrahydrophthalic anhydride, methyl tetrahydrophthalic anhydride, endomethylene tetrahydrophthalic anhydride, methyl endomethylene tetrahydrophthalic anhydride, methyl butenyl tetrahydrophthalic anhydride, dodecenyl succinic anhydride, hexahydrophthalic anhydride, methylhexahydrophthalic anhydride, succinic anhydride, methylcyclohexene dicarboxylic anhydride, chlorendic anhydride, or combinations thereof.

In an embodiment, the reducing agent may include at least one of formic acid, acetic acid, propionic acid, butyric acid, valeric acid, caproic acid, caprylic acid, decanoic acid, lauric acid, myristic acid, palmitic acid, stearic acid, oleic acid, linoleic acid, alpha-linolenic acid, cyclohexanecarboxylic acid, phenylacetic acid, benzoic acid, chlorobenzoic acid, bromobenzoic acid, nitrobenzoic acid, phthalic acid, isophthalic acid, terephthalic acid, salicylic acid, hydroxybenzoic acid, anthranilic acid, aminobenzoic acid, methoxybenzoic acid, glutaric acid, maleic acid, azelaic acid, abietic acid, adipic acid, ascorbic acid, acrylic acid, citric acid, or combinations thereof.

In an embodiment, the composition for conductive adhesive may further include a conductive particle, wherein the conductive particle may include at least one tin (Sn), copper (Cu), silver (Ag), bismuth (Bi), indium (In), lead (Pd), cadmium (Cd), antimony (Sb), gallium (Ga), arsenic (As), germanium (Ge), zinc (Zn), aluminum (Al), gold (Au), silicon (Si), nickel (Ni), phosphorus (P), or alloys selected from combinations thereof.

In an embodiment, the conductive particle may be included in an amount of about 1 vol % to about 60 vol % based on a total volume of the composition for conductive adhesive.

In an embodiment, the composition for conductive adhesive may further include a nonconductive particle, wherein the nonconductive particle may include a polymer particle or an inorganic particle.

In an embodiment of the inventive concept, a semiconductor package includes: a substrate including a substrate pad adjacent to an upper surface thereof; a semiconductor chip including a chip pad corresponding to the substrate pad; solder bonding portions between the substrate and the semiconductor chip; and a conductive adhesive cured product on at least one of the upper surface of the substrate or a lower surface of the semiconductor chip, wherein the conductive adhesive cured product is a cured product of a composition for conductive adhesive, wherein the composition for conductive adhesive includes: a heterocyclic compound containing oxygen, the heterocyclic compound including at least one of an epoxy group or oxetane group; a reductive curing agent including an amine group and a carboxyl group; and a photoinitiator.

In an embodiment, an upper surface of the conductive adhesive cured product may include protruding and recessed sections.

In an embodiment of the inventive concept, a method of manufacturing a semiconductor package includes: providing a substrate including a substrate pad adjacent to an upper surface thereof; providing a semiconductor chip on the substrate, the semiconductor chip including a chip pad corresponding to the substrate pad; providing a conductive adhesive film on at least one of the upper surface of the substrate or a lower surface of the semiconductor chip, the conductive adhesive film including a composition for conductive adhesive; electrically connecting the chip pad and the substrate pad by performing a heating process on at least one of the substrate, the semiconductor chip, or the conductive adhesive film; and forming a conductive adhesive cured product by radiating light onto at least one of the substrate, the semiconductor chip, or the conductive adhesive film, wherein the forming of the conductive adhesive cured product includes forming protruding and recessed sections on an upper surface of the conductive adhesive cured product, wherein the composition for conductive adhesive includes: a heterocyclic compound containing oxygen, the heterocyclic compound including at least one of an epoxy group or oxetane group; a reductive curing agent including an amine group and a carboxyl group; and a photoinitiator.

In an embodiment, the heating process may include a process of radiating infrared radiation (IR) laser, and the light may include ultraviolet (UV) light.

In an embodiment, the providing of the semiconductor chip may include providing a mold contacting one or more surfaces of the semiconductor chip, wherein a lower surface of the mold exposed by the semiconductor chip may include mold protruding and recessed sections.

In an embodiment, the forming of the protruding and recessed sections on the upper surface of the conductive adhesive cured product may include transferring a pattern of the mold protruding and recessed sections of the lower surface of the mold to the upper surface of the conductive adhesive cured product.

In an embodiment, the composition for conductive adhesive may further include conductive particles, wherein the conductive particles between the substrate pad and the chip pad may be fused and wet by the heating process, thereby forming a solder bonding portion.

In an embodiment, each of the conductive adhesive film, the substrate pad, and the chip pad may be provided in plurality, wherein the conductive adhesive films may be spaced apart laterally, and each of the conductive adhesive films may cover an upper surface of each of the substrate pads or a lower surface of each of the chip pads.

In an embodiment, each of the conductive adhesive films may be arranged between the chip pad and the substrate pad, and each of the conductive adhesive films may flow out so as to be arranged on a portion of the upper surface of the substrate, a portion of the lower surface of the semiconductor chip, and a portion of a side surface of the semiconductor chip due to the heating process.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view for describing a semiconductor package manufactured using a composition for conductive adhesive according to an embodiment of the inventive concept;

FIGS. 2 to 4 are cross-sectional views illustrating a method of manufacturing a semiconductor package using a composition for conductive adhesive according to an embodiment of the inventive concept;

FIG. 5A is an image of an upper surface of a conductive adhesive film before light is radiated;

FIG. 5B is an image of an upper surface of a conductive adhesive cured product on which protruding and recessed sections have been formed by light;

FIGS. 6 to 9 are cross-sectional views illustrating a method of manufacturing a semiconductor package using a composition for conductive adhesive according to an embodiment of the inventive concept;

FIG. 10A is an image of a lower surface of a mold;

FIG. 10B is an image of an upper surface of a conductive adhesive cured product to which a lower surface pattern of a mold has been transferred;

FIG. 11 is a cross-sectional view for describing a semiconductor package manufactured using a composition for conductive adhesive according to an embodiment of the inventive concept;

FIGS. 12 to 14 are cross-sectional views illustrating a method of manufacturing a semiconductor package using a composition for conductive adhesive according to an embodiment of the inventive concept;

FIGS. 15 to 18 are cross-sectional views illustrating a method of manufacturing a semiconductor package using a composition for conductive adhesive according to an embodiment of the inventive concept;

FIG. 19 is a cross-sectional view for describing a semiconductor package manufactured using a composition for conductive adhesive according to an embodiment of the inventive concept;

FIGS. 20 to 22 are cross-sectional views illustrating a method of manufacturing a semiconductor package using a composition for conductive adhesive according to an embodiment of the inventive concept; and

FIGS. 23 to 26 are cross-sectional views illustrating a method of manufacturing a semiconductor package using a composition for conductive adhesive according to an embodiment of the inventive concept.

### DETAILED DESCRIPTION

Advantages and features of the inventive concept, and implementation methods thereof will be clarified through following embodiments described with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. Further, the inventive concept is only defined by the scope of claims. Like reference numerals refer to like elements throughout.

The terminology used herein is not for delimiting the embodiments of the inventive concept but for describing the embodiments. The terms of a singular form may include plural forms unless otherwise specified. It will be further understood that the terms “includes”, “including”, “comprises”, and/or “comprising”, when used in this specification, specify the presence of stated elements, steps, operations, and/or components, but do not preclude the presence or addition of one or more other elements, steps, operations, components, and/or groups thereof.

The embodiments of the inventive concept will be described with reference to example cross-sectional views and/or plana views. In the drawings, the dimensions of layers and regions are exaggerated for clarity of illustration. Therefore, the forms of the example drawings may be changed due to a manufacturing technology and/or error tolerance. Therefore, the embodiments of the inventive concept may involve changes of shapes depending on a manufacturing process, without being limited to the illustrated specific forms. Therefore, the regions illustrated in the drawings are merely schematic, and the shapes of the regions exemplify specific shapes of the elements but do not limit the scope of the invention.

The terms used to describe the embodiments of the inventive concept may be interpreted as the meanings known in the art unless the terms are defined differently.

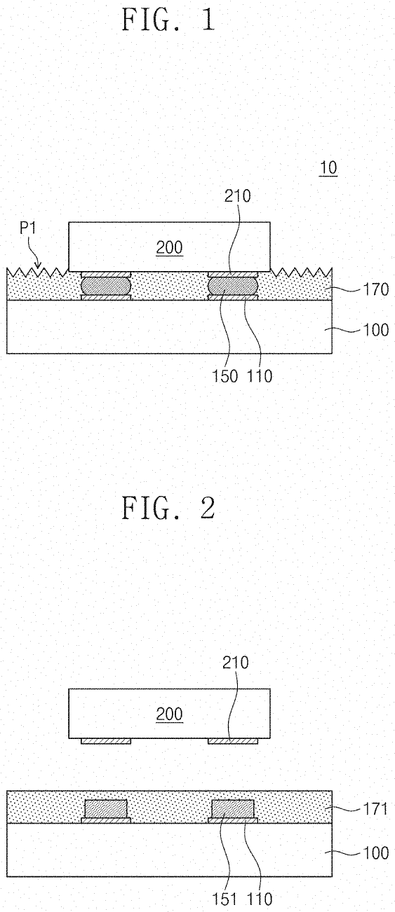

FIG. 1 is a cross-sectional view for describing a semiconductor package manufactured using a composition for conductive adhesive according to an embodiment of the inventive concept.

Referring to FIG. 1, a semiconductor package 10 may include a substrate 100, a semiconductor chip 200, a solder bonding portion 150, and a conductive adhesive cured product 170.

The substrate 100 may be provided. For example, the substrate 100 may be a printed circuit board (PCB). The substrate 100 may include a substrate pad 110 adjacent to an upper surface of the substrate 100. The substrate pad 110 may be provided in plurality. The substrate pads 110 may be exposed on the upper surface of the substrate 100. Substate wiring (not shown) may be provided in the substrate 100. The substrate pads 110 may be electrically connected to the substrate wiring (not shown). In the present disclosure, electrically connecting/joining two components may include directly connecting/joining the two components or indirectly connecting/joining the two components via another conductive component. The substrate pads 110 may include a conductive metal material, for example, at least one metal among copper (Cu), aluminum (Al), tungsten (W), titanium (Ti), nickel (Ni), and gold (Au).

The semiconductor chip 200 may be provided on the substrate 100. For example, the semiconductor chip 200 may include a passive device, an active device, a light-emitting diode, a memory chip, or a logic chip. The semiconductor chip 200 may include a chip pad 210 corresponding to the substrate pad 110. The chip pad 210 may be provided in plurality. The chip pads 210 may be exposed on a lower surface of the semiconductor chip 200. The chip pads 210 may include a conductive metal material, for example, at least one metal among copper (Cu), aluminum (Al), tungsten (W), and titanium (Ti).

The solder bonding portions 150 may be arranged between the substrate 100 and the semiconductor chip 200. The substrate 100 and the semiconductor chip 200 may be electrically connected by the solder bonding portions 150. The solder bonding portions 150 may be arranged between the substrate pads 110 and the chip pads 210. Each of the substrate pads 110 may be electrically connected to a corresponding one among the chip pads 210 via a corresponding one among the solder bonding portions 150.

The conductive adhesive cured product 170 may be arranged on at least one of the upper surface of the substrate 100 or the lower surface of the semiconductor chip 200. The conductive adhesive cured product 170 may be arranged between the substrate 100 and the semiconductor chip 200. The conductive adhesive cured product 170 may fill a space between the solder bonding portions 150 and may seal the solder bonding portions 150. The conductive adhesive cured product 170 may cover the upper surface of the substrate 100, the lower surface of the semiconductor chip 200, and a side surface of the semiconductor chip 200. In some embodiments, the conductive adhesive cured product 170 may cover a lower sidewall of the semiconductor chip 200. An upper surface of the conductive adhesive cured product 170 may include protruding and recessed sections P1. In detail, the upper surface of the conductive adhesive cured product 170 exposed by the semiconductor chip 200 may include the protruding and recessed sections P1. The conductive adhesive cured product 170 may include a cured product of a composition for conductive adhesive. The composition for conductive adhesive may include a curable resin, a reductive curing agent, and a photoinitiator.

The curable resin may include a resin cured by heat and/or light. The curable resin may include a heterocyclic compound containing oxygen. The heterocyclic compound may include at least one of an epoxy group or oxetane group. In some embodiments, the heterocyclic compound may include a plurality of epoxy groups or a plurality of oxetane groups. For example, the heterocyclic compound may include at least one of bisphenol-A type epoxy resin, bisphenol-F type epoxy resin, novolac epoxy resin, hydrogenated bisphenol-A type epoxy resin, octylene oxide, p-butyl phenol glycidyl ether, butyl glycidyl ether, cresyl glycidyl ether, styrene oxide, allyl glycidyl ether, phenyl glycidyl ether, butadiene dioxide, divinylbenzene dioxide, diglycidyl ether, butanediol diglycidyl ether, limonene dioxide, vinylcyclohexene dioxide, diethylene glycol diglycidyl ether, 4-vinylcyclohexene dioxide, cyclohexene vinyl monoxide, (3,4-epoxycyclohexyl)methyl 3,4-epoxycyclohexylcarboxylate, 3,4-epoxycyclohexylmethyl methacrylate, 3,4-epoxycyclohexanecarboxylate, 2-(3,4-epoxycyclohexyl)-1,3-dioxolane, bis(3,4-epoxycyclohexylmethyl)adipate, 3-methyloxetane, 2-methyloxetane, 3-oxetanol, 2-methyleneoxetane, 3-methyl-3-hydroxymethyloxetane, 3-ethyl-3-hydroxymethyloxetane, 3,3-oxetanedimethanethiol, 2-ethylhexyloxetane, 4-(3-methyloxetan-3-yl)benzonitrile, N-(2,2-dimethylpropyl)-3-methyl-3-oxetanemethanamine, N-(1,2-dimethylbutyl)-3-methyl-3-oxetanemethanamine, xylene bis oxetane, 3-ethyl-3[{(3-ethyloxetan-3-yl)methoxy}methyl]oxetane, (3-ethyloxetan-3-yl)methyl methacrylate, 4-[(3-ethyloxetan-3-yl)methoxy]butan-1-ol, combinations thereof, or chemical reactants thereof. However, the heterocyclic compound is not limited to the above example materials.

The reductive curing agent may reduce a metal surface by removing a metal oxide of the metal surface, and, simultaneously, may chemically react with the epoxy group or oxetane group of the heterocyclic compound so as to be cured. The reductive curing agent may include an amine group and a carboxyl group. In some embodiments, the reductive curing agent may include a plurality of amine groups and a plurality of carboxyl groups. For example, the reductive curing agent may include at least one of alpha(α)-amino acid, beta(β)-amino acid, gamma(γ)-amino acid, delta(δ)-amino acid, anthranilic acid, 3-aminobenzoic acid, para-aminobenzoic acid, or combinations thereof. For example, the reductive curing agent may include at least one of glycine, alanine, valine, leucine, isoleucine, lysine, arginine, histidine, aspartic acid, asparagine, glutamine, glutamic acid, phenylalanine, tyrosine, tryptophan, cysteine, methionine, serine, ornithine, 3-phenylserine, threonine, L-dopa, norleucine, penicillamine, sarcosine, proline, hydroxyproline, 3-hydroxyproline, 3,4-dihydroproline, pipecolic acid, β-alanine, 3-aminobutyric acid, isoserine, 3-aminoisobutyric acid, 3-amino-2-phenylpropionic acid, 3-amino-5-methylhexanoic acid, 3-amino-4-phenylbutyric acid, 3-amino-4-hydroxybutyric acid, 3-amino-4-hydroxypentanoic acid, 3-amino-4-methylpentanoic acid, 3-amino-3-phenylpropionic acid, pyrrolidine-3-carboxylic acid, γ-aminobutyric acid, 4-amino-3-hydroxybutyric acid, 3-pyrrolidine-2-yl-propionic acid, 3-aminocyclohexanecarboxylic acid, 4-guanidinobutyric acid, 4-aminobenzoic acid, 3-aminobenzoic acid, 2-aminobenzoic acid, 3,5-diaminobenzoic acid, 4-aminosalicylic acid, 5-aminosalicylic acid, 3-aminoisonicotinic acid, 4-aminonicotinic acid, 5-aminonicotinic acid, 2-aminonicotinic acid, 6-aminonicotinic acid, 2-aminoisonicotinic acid, 6-aminopicolinic acid, combinations thereof, or chemical reactants thereof. However, the reductive curing agent is not limited to the above example materials.

A mixture ratio of the heterocyclic compound and the reductive curing agent may satisfy Conditional Expression 1 below.

0.5≤(b+c)/a≤1.5, a>0, b≥0, c>0 [Conditional Expression 1]

In Conditional Expression 1, ‘a’ may denote a mole number of a heterocycle in the heterocyclic compound. That is, ‘a’ may denote a mole number of an epoxy group or oxetane group in the heterocyclic compound. ‘b’ may denote a mole number of active hydrogen in the amine group included in the reductive curing agent. ‘c’ may denote a mole number of the carboxyl group included in the reductive curing agent. In the present disclosure, active hydrogen, which is in a highly reactive atomic state, may represent hydrogen atoms bonded to O or N with high electronegativity, such as OH, NH₂, and the like. That is, the active hydrogen may represent a hydrogen atom bonded to a nitrogen atom of amine, and ‘b’ may denote a mole number of hydrogen bonded to a nitrogen atom of the amine group included in the reductive curing agent. Here, when (b+c)/a is about 0.5 to about 1.5, the composition for conductive adhesive according to an embodiment of the inventive concept may have improved curing characteristics and reducing characteristics. However, when (b+c)/a is less than about 0.5 or greater than about 1.5, the curing characteristics and reducing characteristics of the composition for conductive adhesive may deteriorate.

The photoinitiator may be dissociated by light so as to initiate the epoxy group or oxetane group included in the heterocyclic compound, thus causing a polymerization reaction. Furthermore, the photoinitiator may execute a function of reducing a metal surface by removing a metal oxide of the metal surface. The photoinitiator may include at least one of photo-acid generators, photo-base generators, or combinations thereof. For example, the photoinitiator may include at least one of onium salt (e.g., iodonium salt, sulfonium salt, phosphonium salt, diazonium salt, pyridinium salt, or imides) such as 3-methyl-2-butenyltetramethylenesulfonium hexafluoroantimonate salt, ytterbium trifluoromethanesulfonate salt, samarium trifluoromethanesulfonate salt, erbium trifluoromethanesulfonate salt, triarylsulfonium hexafluoroantimonate salt, triarylsulfonium hexafluorophosphate salt, lanthanum trifluoromethanesulfonate salt, tetrabutylphosphonium methanesulfonate salt, ethyltriphenylphosphonium bromide salt, diphenyliodonium hexafluoroantimonate salt, diphenyliodonium hexafluorophosphate salt, ditolyliodonium hexafluorophosphate salt, 9-(4-hydroxyethoxyphenyl)thianthrenium hexafluorophosphate salt, 1-(3-methylbut-2-enyl)tetrahydro-1H-thiophenium hexafluoroantimonate salt, and the like, 2-(9-Oxoxanthen-2-yl)propionic Acid 1,5,7-Triazabicyclo[4.4.0]dec-5-ene Salt, or combinations thereof. However, the photoinitiator is not limited to the above example materials. For example, the photoinitiator may be included in an amount of about 0.1 to about 10 parts by weight based on 100 parts by weight of the heterocyclic compound.

The composition for conductive adhesive may further include at least one of amine-based curing agent, acid anhydride-based curing agent, or reducing agent.

The amine-based curing agent may chemically react with the epoxy group or oxetane group included in the heterocyclic compound so as to be cured. The amine-based curing agent may include an amine group. In some embodiments, the amine-based curing agent may include a plurality of amine groups. The amine-based curing agent may not include a carboxyl group. For example, the amine-based curing agent may include at least one of diethylenetriamine, triethylenediamine, triethylenetetramine, tetraethylenepentamine, diethylaminopropyleneamine, aminoethylpiperazine, menthane diamine, isophorone diamine, methaphenilene diamine, diaminodiphenylmethane, diaminodiphenylsulfone, 2-methyl-4-nitroaniline, dicyandiamide, 2-methylimidazole, 2-ethyl-4-methylimidazole, 2,4-dimethylimidazole, 2-phenylimidazole, 2-phenyl-4-methylimidazole, 1-cyanoethyl-2-undecylimidazolium trimellitate, epoxyimidazole adduct, combinations thereof, or chemical reactants thereof.

The acid anhydride-based curing agent may chemically react with the epoxy group or oxetane group included in the heterocyclic compound so as to be cured. The acid anhydride-based curing agent may include an acid anhydride group. In some embodiments, the acid anhydride-based curing agent may include a plurality of acid anhydride groups. For example, the acid anhydride-based curing agent may include at least one of phthalic anhydride, trimellitic anhydride, pyromellitic dianhydride, benzophenonetetracarboxylic dianhydride, maleic anhydride, tetrahydrophthalic anhydride, methyl tetrahydrophthalic anhydride, endomethylene tetrahydrophthalic anhydride, methyl endomethylene tetrahydrophthalic anhydride, methyl butenyl tetrahydrophthalic anhydride, dodecenyl succinic anhydride, hexahydrophthalic anhydride, methylhexahydrophthalic anhydride, succinic anhydride, methylcyclohexene dicarboxylic anhydride, chlorendic anhydride, combinations thereof, or chemical reactants thereof.

The reducing agent may execute a function of reducing a metal surface by removing a metal oxide of the metal surface, and may chemically react with the epoxy group or oxetane group included in the heterocyclic compound so as to be cured. The reducing agent may include a carboxyl group. In some embodiments, the reducing agent may include a plurality of carboxyl groups. The reducing agent may not include an amine group. For example, the reducing agent may include at least one of carboxylic acids such as formic acid, acetic acid, propionic acid, butyric acid, valeric acid, caproic acid, caprylic acid, decanoic acid, lauric acid, myristic acid, palmitic acid, stearic acid, oleic acid, linoleic acid, alpha-linolenic acid, cyclohexanecarboxylic acid, phenylacetic acid, benzoic acid, chlorobenzoic acid, bromobenzoic acid, nitrobenzoic acid, phthalic acid, isophthalic acid, terephthalic acid, salicylic acid, hydroxybenzoic acid, anthranilic acid, aminobenzoic acid, methoxybenzoic acid, glutaric acid, maleic acid, azelaic acid, abietic acid, adipic acid, ascorbic acid, acrylic acid, citric acid, and the like, combinations thereof, or chemical reactants thereof.

A mixture ratio of the amine-based curing agent, the acid anhydride-based curing agent, and the reducing agent may satisfy Conditional Expression 2 below.

0.5≤(b+c+d+e+f)/a≤1.5, (b+c)≥(d+e+f), a>0, b≥0, c>0, d≥0, e≥0, f≥0, d+e+f≠0 [Conditional Expression 2]

In Conditional Expression 2, ‘a’ may denote a mole number of a heterocycle in the heterocyclic compound. That is, ‘a’ may denote a mole number of an epoxy group or oxetane group in the heterocyclic compound. ‘b’ may denote a mole number of active hydrogen in the amine group included in the reductive curing agent. That is, ‘b’ may denote a mole number of hydrogen bonded to a nitrogen atom of the amine group included in the reductive curing agent. ‘c’ may denote a mole number of the carboxyl group included in the reductive curing agent. ‘d’ may denote a mole number of active hydrogen in the amine group included in the amine-based curing agent. That is, ‘d’ may denote a mole number of hydrogen bonded to a nitrogen atom of the amine group included in the amine-based curing agent. ‘e’ may denote a mole number of the acid anhydride group included in the acid anhydride-based curing agent. ‘f’ may denote a mole number of the carboxyl group included in the reducing agent. Here, when (b+c+d+e+f)/a is about 0.5 to about 1.5, the composition for conductive adhesive according to an embodiment of the inventive concept may have improved curing characteristics and reducing characteristics. However, when (b+c+d+e+f)/a is less than about 0.5 or greater than about 1.5, the curing characteristics and reducing characteristics of the composition for conductive adhesive may deteriorate. Furthermore, in the case of (b+c)<(d+e+f), a pot life characteristic of the composition of conductive adhesive may deteriorate. After materials in the composition for conductive adhesive are mixed, a viscosity thereof may gradually increase due to reaction between the materials, thus causing a state in which the composition for conductive adhesive may not be used. In the present disclosure, the pot life may represent a time that elapses until the composition for conductive adhesive is able to be used after the materials in the composition for conductive adhesive are mixed.

The composition for conductive adhesive may further include at least one of conductive particles, nonconductive particles, deforming agents, catalysts, latent curing agents, thermal-acid generators, sensitizers, chelating agents, dyes, carbon black, graphene, carbon nanotubes, fullerenes, or combinations thereof. The deforming agent may have a function of controlling surface tension. For example, the conductive particles may include at least one of metals or nonmetals such as tin (Sn), copper (Cu), silver (Ag), bismuth (Bi), indium (In), lead (Pd), cadmium (Cd), antimony (Sb), gallium (Ga), arsenic (As), germanium (Ge), zinc (Zn), aluminum (Al), gold (Au), silicon (Si), nickel (Ni), and phosphorus (P), or alloys selected from combinations thereof. The alloys, for example, may have a composition ratio of 96.5Sn/3.5Ag, 55.5Bi/44.5Pb, 96.5Sn/3.0Ag/0.5Cu, 52Bi/32Pb/16Sn, 58Bi/42Sn, 57Bi/42Sn/1Ag, 50In/50Sn, 33In/67Bi, 17Sn/26In/57Bi, or 52In/48Sn, but is not limited thereto.

The composition for conductive adhesive of an embodiment of the inventive concept may electrically bond a semiconductor chip and a substrate, and, thereafter, may be cured so as to protect a bonding portion connecting the semiconductor chip and the substrate. The composition for conductive adhesive of an embodiment of the inventive concept may be initiated by light and heat, and, thus, the curing characteristic of the composition for conductive adhesive may be improved, and metal oxide film removal efficiency and pot life characteristic may also be improved. Accordingly, bonding processes of various methods may be possible, in which heating process and light radiation are combined. In addition, a pattern may be formed on a surface of a cured product of the composition for conductive adhesive by a light radiation process, and a functionality may be imparted accordingly. Ultimately, the composition for conductive adhesive of an embodiment of the inventive concept may be applied in the fields of various electronic packages, such as display, signage, AR/VR display, camera module, sensor, semiconductor, power semiconductor, or electronic part.

FIGS. 2 to 4 are cross-sectional views illustrating a method of manufacturing a semiconductor package using a composition for conductive adhesive according to an embodiment of the inventive concept. The same descriptions as provided above are omitted below.

Referring to FIG. 2, the substrate 100 may be provided. The substrate 100 may include the substrate pads 110 adjacent to the upper surface of the substrate 100. Solder bumps 151 may be formed on at least one of the substrate pads 110 or the chip pads 210. The solder bumps 151 may include a conductive material, and may have a shape of at least one of a solder ball, bump, or pillar. For example, the solder bumps 151 may include at least one of metals or nonmetals such as tin (Sn), copper (Cu), silver (Ag), bismuth (Bi), indium (In), lead (Pd), cadmium (Cd), antimony (Sb), gallium (Ga), arsenic (As), germanium (Ge), zinc (Zn), aluminum (Al), gold (Au), silicon (Si), nickel (Ni), and phosphorus (P), or alloys selected from combinations thereof. The alloys, for example, may have a composition ratio of 96.5Sn/3.5Ag, 55.5Bi/44.5Pb, 96.5Sn/3.0Ag/0.5Cu, 52Bi/32Pb/16Sn, 58Bi/42Sn, 57Bi/42Sn/1Ag, 50In/50Sn, 33In/67Bi, 17Sn/26In/57Bi, or 52In/48Sn, but is not limited thereto. A conductive adhesive film 171 may be formed on at least one of the upper surface of the substrate 100 or the lower surface of the semiconductor chip 200. The conductive adhesive film 171 may cover the solder bumps 151. Forming the conductive adhesive film 171 may include applying the composition for conductive adhesive. Forming the solder bump 151 may be performed after or before the conductive adhesive film 171 is formed.

The semiconductor chip 200 may be provided on the substrate 100. The semiconductor chip 200 may include the chip pads 210 corresponding to the substrate pads 110.

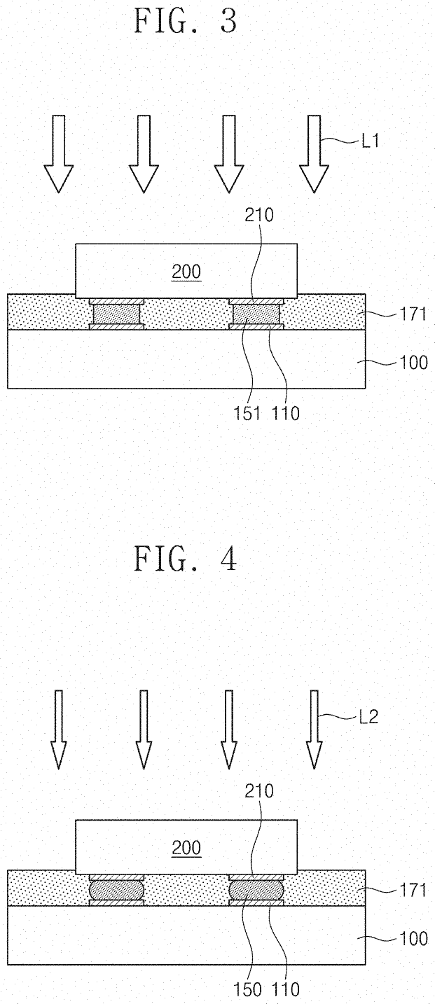

Referring to FIG. 3, the semiconductor chip 200 may be aligned so that each of the chip pads 210 is arranged on the corresponding substrate pad 110 and each of the solder bumps 151 is arranged between the substrate pad 110 and the chip pad 210. Accordingly, the chip pads 210 may directly contact the solder bumps 151. The semiconductor chip 200 may be arranged so that the lower surface of the semiconductor chip 200 covers a portion of an upper surface of the conductive adhesive film 171. In some embodiments, the upper surface of the conductive adhesive film 171 may be positioned at a level higher than the lower surface of the semiconductor chip 200. In some embodiments, the conductive adhesive film 171 may cover sidewalls of the semiconductor chip 200. However, an embodiment of the inventive concept is not limited thereto, and, thus, unlike the illustration, the upper surface of the conductive adhesive film 171 may be positioned at a level that is substantially flush with or lower than the lower surface of the semiconductor chip 200. In the present disclosure, the level may represent a vertical height from the upper surface of the substrate 100.

A heating process L1 may be performed on at least one of the substrate 100, the semiconductor chip 200, or the conductive adhesive film 171. For example, the heating process may include at least one of infrared heating, resistance heating, arc heating, induction heating, dielectric heating, or electron beam heating. For example, the infrared heating may include a process of radiating infrared radiation (IR) laser. However, an embodiment of the inventive concept is not limited thereto, and any process capable of controlling a temperature of the composition for conductive adhesive may be used.

Referring to FIG. 4, the solder bonding portions 150 may be formed by the heating process L1, and the chip pads 210 and the substrate pads 110 may be electrically connected by the solder bonding portions 150. Forming the solder bonding portions 150 may include meting the solder bumps 151 by the heating process L1, wetting the solder bumps 151 on the chip pads 210 and the substrate pads 110, and cooling the melted solder bumps 151. For example, a process of forming the solder bonding portions 150 may include a reflow process. In some embodiments, a pressing process may be further performed on the semiconductor chip 200 in order to efficiently connect the chip pads 210 and the substrate pads 110. In detail, the heating process L1 may be performed during the pressing process in which the semiconductor chip 200 provided on the substrate 100 is pressed with a specific pressure.

A light radiation process L2 may be performed on at least one of the substrate 100, the semiconductor chip 200, or the conductive adhesive film 171. For example, the light radiation process L2 may include a process of radiating ultraviolet (UV) light. According to an embodiment of the inventive concept, an order in which the heating process L1 and the light radiation process L2 are performed may not be particularly limited. For example, the light radiation process L2 may be performed after the heating process L1, or the heating process L1 may be performed after the light radiation process L2. According to an embodiment of the inventive concept, the light radiation process L2 may be performed during the pressing process in which the semiconductor chip 200 provided on the substrate 100 is pressed with a specific pressure.

Referring back to FIG. 1, the conductive adhesive cured product 170 may be formed by the light radiation process L2. Forming the conductive adhesive cured product 170 may include forming the protruding and recessed sections P1 on the upper surface of the conductive adhesive cured product 170 while curing the conductive adhesive film 171. The upper surface of the conductive adhesive film 171 may shrink and be cured by the light radiation process L2, and the protruding and recessed sections P1 may be formed on the upper surface of the conductive adhesive cured product 170. According to an embodiment of the inventive concept, a post-curing process may be further performed to improve chemical and mechanical reliability of the conductive adhesive cured product 170 by increasing the degree of cure of the conductive adhesive cured product 170. For example, the post-curing process may be performed at a temperature of about 50° C. to about 300° C.

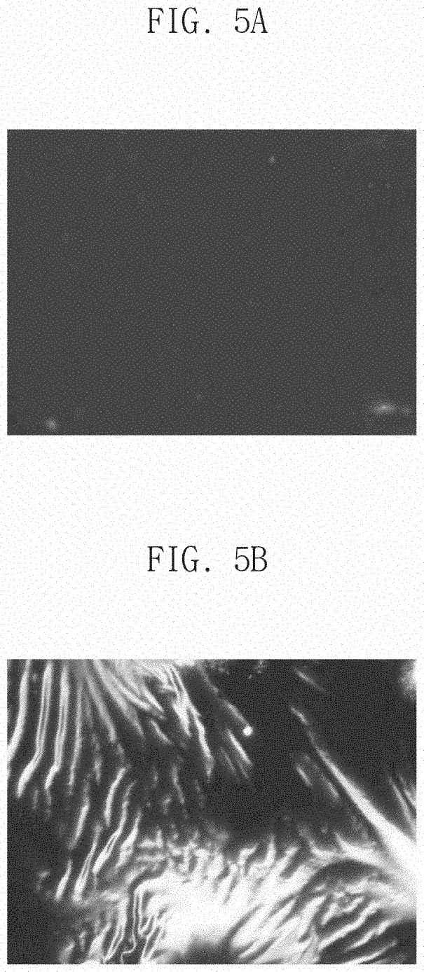

FIG. 5A is an image of the upper surface of the conductive adhesive film 171 before the light radiation process L2 is performed. FIG. 5B is an image of the upper surface of the conductive adhesive cured product 170 on which the protruding and recessed sections P1 are formed by the light radiation process L2. Referring to FIG. 5A, it may be confirmed that the upper surface of the conductive adhesive film 171 is substantially flat before the light radiation process L2 is performed. Referring to FIG. 5B, it may be confirmed that the protruding and recessed sections P1 are formed on the upper surface of the conductive adhesive cured product 170 by the light radiation process L2.

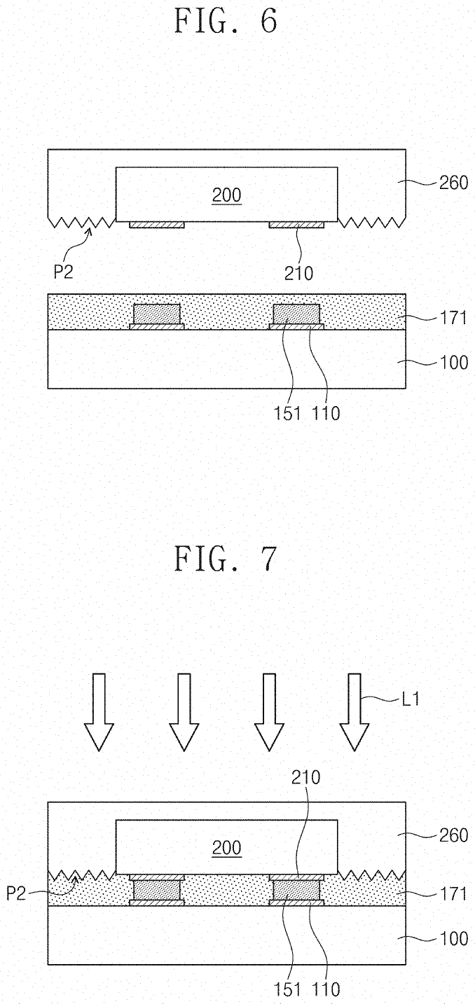

FIGS. 6 to 9 are cross-sectional views illustrating a method of manufacturing a semiconductor package using a composition for conductive adhesive according to an embodiment of the inventive concept. The same descriptions as provided above are omitted below.

Referring to FIG. 6, the substrate 100 may be provided. The substrate 100 may include the substrate pads 110 adjacent to the upper surface of the substrate 100. Solder bumps 151 may be formed on at least one of the substrate pads 110 or the chip pads 210. A conductive adhesive film 171 may be formed on at least one of the upper surface of the substrate 100 or the lower surface of the semiconductor chip 200. The conductive adhesive film 171 may cover the solder bumps 151. Forming the conductive adhesive film 171 may include applying the composition for conductive adhesive.

The semiconductor chip 200 may be provided on the substrate 100. The semiconductor chip 200 may include the chip pads 210 corresponding to the substrate pads 110. Providing the semiconductor chip 200 may include providing a mold 260 contacting one or more surfaces of the semiconductor chip 200. The mold 260 may cover the upper surface of the semiconductor chip 200 or the upper surface and sidewall thereof. The mold 260 may expose the lower surface of the semiconductor chip 200 and the chip pads 210. The lower surface of the mold 260 exposed by the semiconductor chip 200 may include mold protruding and recessed sections P2. For example, the mold 260 may include polydimethylsiloxane (PDMS).

Referring to FIG. 7, the semiconductor chip 200 may be aligned so that each of the chip pads 210 is arranged on the corresponding substrate pad 110 and each of the solder bumps 151 is arranged between the substrate pad 110 and the chip pad 210. Accordingly, the chip pads 210 may directly contact the solder bumps 151. The semiconductor chip 200 may be arranged so that the lower surface of the semiconductor chip 200 covers a portion of an upper surface of the conductive adhesive film 171. The mold 260 may be arranged so that the lower surface of the mold 260 covers another portion of the upper surface of the conductive adhesive film 171.

A heating process L1 may be performed on at least one of the substrate 100, the semiconductor chip 200, or the conductive adhesive film 171. For example, the heating process may include at least one of infrared heating, resistance heating, arc heating, induction heating, dielectric heating, or electron beam heating. For example, the infrared heating may include a process of radiating infrared radiation (IR) laser.

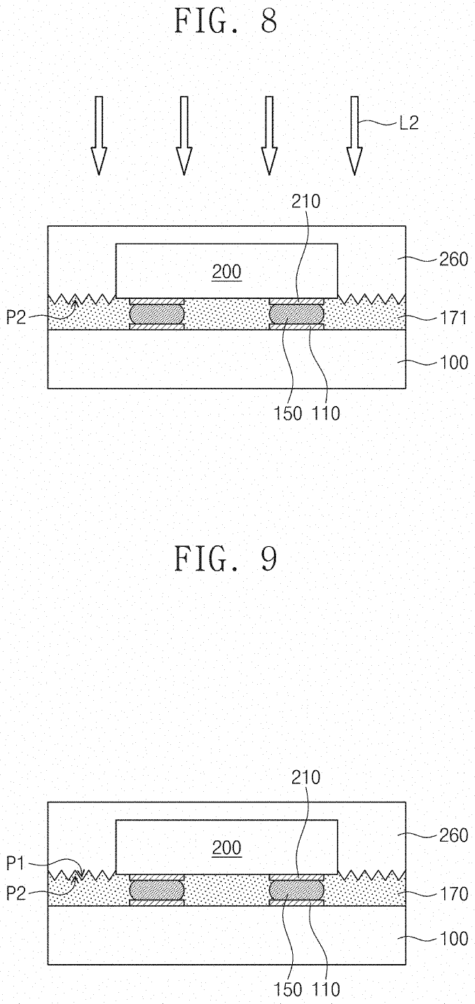

Referring to FIG. 8, the solder bonding portions 150 may be formed by the heating process L1, and the chip pads 210 and the substrate pads 110 may be electrically connected. Forming the solder bonding portions 150 may include meting the solder bumps 151 by the heating process L1, wetting the solder bumps 151 on the chip pads 210 and the substrate pads 110, and cooling the melted solder bumps 151. For example, a process of forming the solder bonding portions 150 may include a reflow process. In some embodiments, a pressing process may be further performed on the semiconductor chip 200 in order to efficiently connect the chip pads 210 and the substrate pads 110. In detail, the heating process L1 may be performed during the pressing process in which the semiconductor chip 200 provided on the substrate 100 is pressed with a specific pressure.

A light radiation process L2 may be performed on at least one of the substrate 100, the semiconductor chip 200, or the conductive adhesive film 171. For example, the light radiation process L2 may include a process of radiating ultraviolet (UV) light. According to an embodiment of the inventive concept, an order in which the heating process L1 and the light radiation process L2 are performed may not be particularly limited. According to an embodiment of the inventive concept, the light radiation process L2 may be performed during the pressing process in which the semiconductor chip 200 provided on the substrate 100 is pressed with a specific pressure.

According to an embodiment of the inventive concept, it may be difficult for the lower surface of the mold 260 to directly contact the upper surface of the conductive adhesive film 171 when the mold 260 covers only the upper surface or a portion of the upper surface and sidewall of the semiconductor chip 200 unlike the illustrations of the FIGS. 6 to 9; however, in this case, the lower surface of the mold 260 may directly contact the upper surface of the conductive adhesive film 171 as the mold 260 is deformed due to the pressing process.

Referring to FIG. 9, the conductive adhesive cured product 170 may be formed by the light radiation process L2. Forming the conductive adhesive cured product 170 may include transferring a pattern of the mold protruding and recessed sections P2 of the lower surface of the mold 260 to the upper surface of the conductive adhesive film 171 and curing the conductive adhesive film 171. Accordingly, the protruding and recessed sections P1 may be formed on the upper surface of the conductive adhesive cured product 170 by the light radiation process L2.

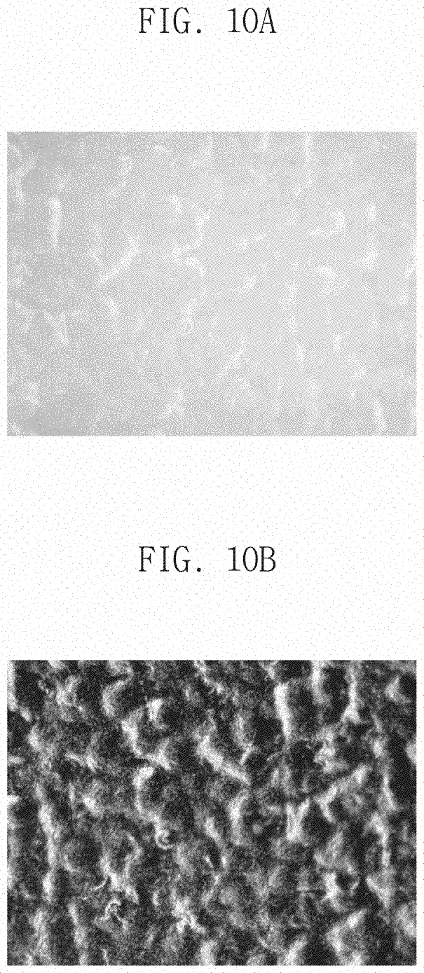

FIG. 10A is an image of the lower surface of the mold 260. FIG. 10B is an image of the upper surface of the conductive adhesive cured product 170 on which a lower surface pattern of the mold 260 has been transferred by the light radiation process L2. Referring to FIGS. 10A and 10B, it may be confirmed that the lower surface pattern of the mold 260 is transferred to the upper surface of the conductive adhesive film 171, and the protruding and recessed sections P1 are formed on the upper surface of the conductive adhesive cured product 170.

Referring back to FIG. 1, the mold 260 may be removed.

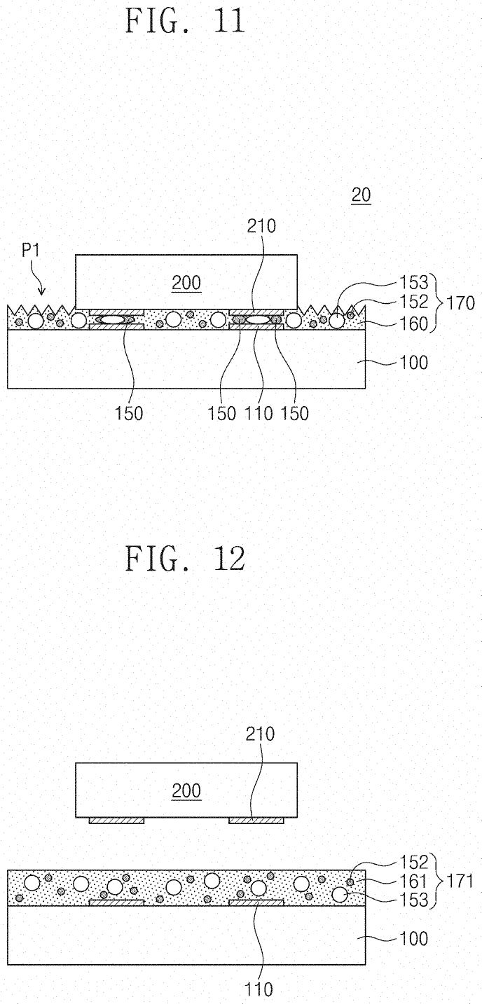

FIG. 11 is a cross-sectional view for describing a semiconductor package manufactured using a composition for conductive adhesive according to an embodiment of the inventive concept. The same descriptions as provided above are omitted below.

Referring to FIG. 11, a semiconductor package 20 may include the substrate 100, the semiconductor chip 200, the solder bonding portion 150, and the conductive adhesive cured product 170.

The substrate 100 may be provided. The substrate 100 may include the substrate pads 110 adjacent to the upper surface of the substrate 100. The semiconductor chip 200 may be provided on the substrate 100. The semiconductor chip 200 may include chip pads 210 corresponding to the substrate pads 110.

The solder bonding portions 150 may be arranged between the substrate 100 and the semiconductor chip 200. The substrate 100 and the semiconductor chip 200 may be electrically connected by the solder bonding portions 150. The solder bonding portions 150 may be arranged between the substrate pads 110 and the chip pads 210. Each of the substrate pads 110 may be electrically connected to a corresponding one among the chip pads 210 via corresponding one or more among the solder bonding portions 150.

The conductive adhesive cured product 170 may be arranged on at least one of the upper surface of the substrate 100 or the lower surface of the semiconductor chip 200. The conductive adhesive cured product 170 may be arranged between the substrate 100 and the semiconductor chip 200. The conductive adhesive cured product 170 may fill a space between the solder bonding portions 150 and may seal the solder bonding portions 150. The conductive adhesive cured product 170 may cover the upper surface of the substrate 100, the lower surface of the semiconductor chip 200, and a side surface of the semiconductor chip 200. In some embodiments, the conductive adhesive cured product 170 may cover a lower sidewall of the semiconductor chip 200. An upper surface of the conductive adhesive cured product 170 may include protruding and recessed sections P1. In detail, the upper surface of the conductive adhesive cured product 170 exposed by the semiconductor chip 200 may include the protruding and recessed sections P1.

The conductive adhesive cured product 170 may include a cured product 160 of a composition 161 for conductive adhesive, a conductive particle 152, and a nonconductive particle 153. The composition 161 for conductive adhesive may include a heterocyclic compound including at least one of an epoxy group or an oxetane group, a reductive curing agent including an amine group and a carboxyl group, and a photoinitiator. The descriptions provided above with reference to FIG. 1 may also apply to the heterocyclic compound, the reductive curing agent, and the photoinitiator.

The composition 161 for conductive adhesive may further include at least one of an amine-based curing agent including an amine group, an acid anhydride-based curing agent including an acid anhydride group, or a reducing agent including a carboxyl group. The descriptions provided above with reference to FIG. 1 may also apply to the amine-based curing agent, the acid anhydride-based curing agent, and the reducing agent.

The composition 161 for conductive adhesive may further include at least one of deforming agents, catalysts, latent curing agents, thermal-acid generators, sensitizers, chelating agents, dyes, carbon black, graphene, carbon nanotubes, fullerenes, or combinations thereof.

The conductive particle 152 may include, for example, a solder particle. The conductive particle 152 may be provided in plurality. The conductive particles 152 may include a conductive material, for example, at least one of tin (Sn), copper (Cu), silver (Ag), bismuth (Bi), indium (In), lead (Pd), or alloys thereof. The alloys, for example, may have a composition ratio of 96.5Sn/3.5Ag, 55.5Bi/44.5Pb, 96.5Sn/3.0Ag/0.5Cu, 52Bi/32Pb/16Sn, 58Bi/42Sn, 57Bi/42Sn/1Ag, 50In/50Sn, 33In/67Bi, 17Sn/26In/57Bi, or 52In/48Sn, but is not limited thereto. For example, the conductive particle 152 may have a diameter of about 5 nm to about 5 mm. The conductive particles 152 may be included in an amount of more than 0 vol % and not greater than about 60 vol % or about 1 vol % to about 60 vol % based on the total volume of the composition for conductive adhesive. The size and/or content of the conductive particles 152 is not limited to the above-mentioned ranges, and may be variously changed.

The solder bonding portion 150 may be formed by fusing the conductive particles 152 provided between the substrate pads 110 and the chip pads 210 and wetting the conductive particles on the substrate pads 110 and the chip pads 210. In the present disclosure, the wetting may represent spreading of a liquid or solid on a solid surface. The substrate pads 110 and the chip pads 210 may be electrically connected by the solder bonding portion 150 between the substrate pads 110 and the chip pads 210.

The nonconductive particle 153 may function to adjust or maintain a distance between the substrate 100 and the semiconductor chip 200 during fusing and wetting of solder particles, and prevent energization between the adjacent solder bonding portions 150. The nonconductive particle 153 may be provided in plurality. For example, the nonconductive particles 153 may include polymer particles or inorganic particles. For example, the polymer particles may include at least one of acrylic polymer-based particles such as polymethylmethacrylate (PMMA) and polybutylmethacrylate (PBMA), polycarbonate-based particles, styrene polymer-based particles such as polystyrene, or silicone-based particles, and the inorganic particles may include at least one of alumina, silica, boron nitride, or silicon carbide.

FIGS. 12 to 14 are cross-sectional views illustrating a method of manufacturing a semiconductor package using a composition for conductive adhesive according to an embodiment of the inventive concept. The same descriptions as provided above are omitted below.

Referring to FIG. 12, the substrate 100 may be provided. The substrate 100 may include the substrate pads 110 adjacent to the upper surface of the substrate 100. A conductive adhesive film 171 may be formed on at least one of the upper surface of the substrate 100 or the lower surface of the semiconductor chip 200. The conductive adhesive film 171 may cover the upper surface of the substrate 100 and the substrate pads 110. The conductive adhesive film 171 may include a composition 161 for conductive adhesive, conductive particles 152, and nonconductive particles 153. Forming the conductive adhesive film 171 may include applying a composition including the composition 161 for conductive adhesive, the conductive particles 152, and the nonconductive particles 153.

The semiconductor chip 200 may be provided on the substrate 100. The semiconductor chip 200 may include the chip pads 210 corresponding to the substrate pads 110.

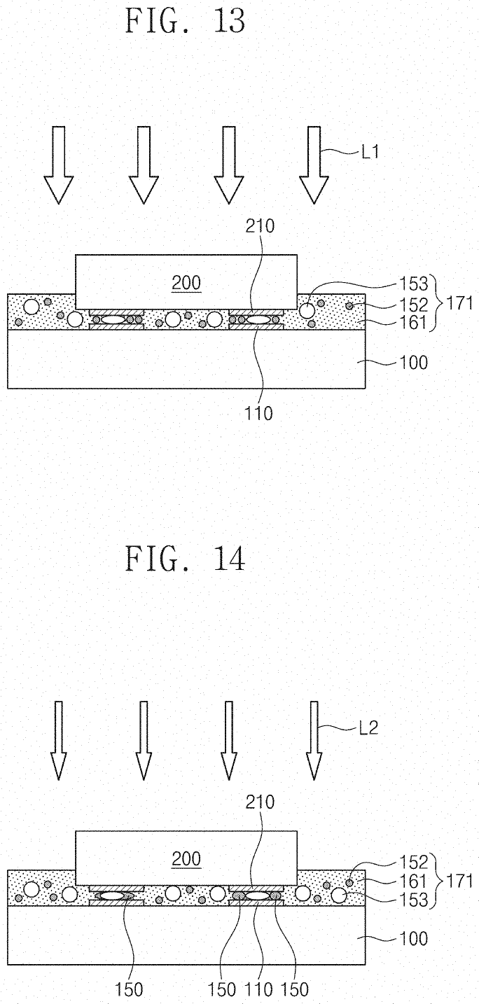

Referring to FIG. 13, the semiconductor chip 200 may be aligned so that each of the chip pads 210 is arranged on the corresponding substrate pad 110. Accordingly, the conductive particles 152 and the nonconductive particles 153 may be arranged between the chip pads 210 and the substrate pads 110. The semiconductor chip 200 may be arranged so that the lower surface of the semiconductor chip 200 covers a portion of an upper surface of the conductive adhesive film 171. In some embodiments, the upper surface of the conductive adhesive film 171 may be positioned at a level higher than the lower surface of the semiconductor chip 200. However, an embodiment of the inventive concept is not limited thereto, and, thus, unlike the illustration, the upper surface of the conductive adhesive film 171 may be positioned at a level that is substantially flush with or lower than the lower surface of the semiconductor chip 200.

A heating process L1 may be performed on at least one of the substrate 100, the semiconductor chip 200, or the conductive adhesive film 171. For example, the heating process may include at least one of resistance heating, arc heating, induction heating, dielectric heating, infrared heating, or electron beam heating. For example, the infrared heating may include a process of radiating infrared radiation (IR) laser.

Referring to FIG. 14, the conductive particles 152 between the substrate pads 110 and the chip pads 210 may be fused and wet by the heating process L1, thereby forming the solder bonding portions 150. Accordingly, the substrate pads 110 and the chip pads 210 may be electrically connected by the solder bonding portions 150 between the substrate pads 110 and the chip pads 210. In some embodiments, a pressing process may be further performed on the semiconductor chip 200 for efficient fusing and wetting of the conductive particles 152. In detail, the heating process L1 may be performed during the pressing process in which the semiconductor chip 200 provided on the substrate 100 is pressed with a specific pressure.

A light radiation process L2 may be performed on at least one of the substrate 100, the semiconductor chip 200, or the conductive adhesive film 171. For example, the light radiation process L2 may include a process of radiating ultraviolet (UV) light. According to an embodiment of the inventive concept, an order in which the heating process L1 and the light radiation process L2 are performed may not be particularly limited. For example, the light radiation process L2 may be performed after the heating process L1, or the heating process L1 may be performed after the light radiation process L2. According to an embodiment of the inventive concept, the light radiation process L2 may be performed during the pressing process in which the semiconductor chip 200 provided on the substrate 100 is pressed with a specific pressure.

Referring back to FIG. 11, the conductive adhesive cured product 170 may be formed by the light radiation process L2. Forming the conductive adhesive cured product 170 may include forming the protruding and recessed sections P1 on the upper surface of the conductive adhesive cured product 170 while curing the conductive adhesive film 171.

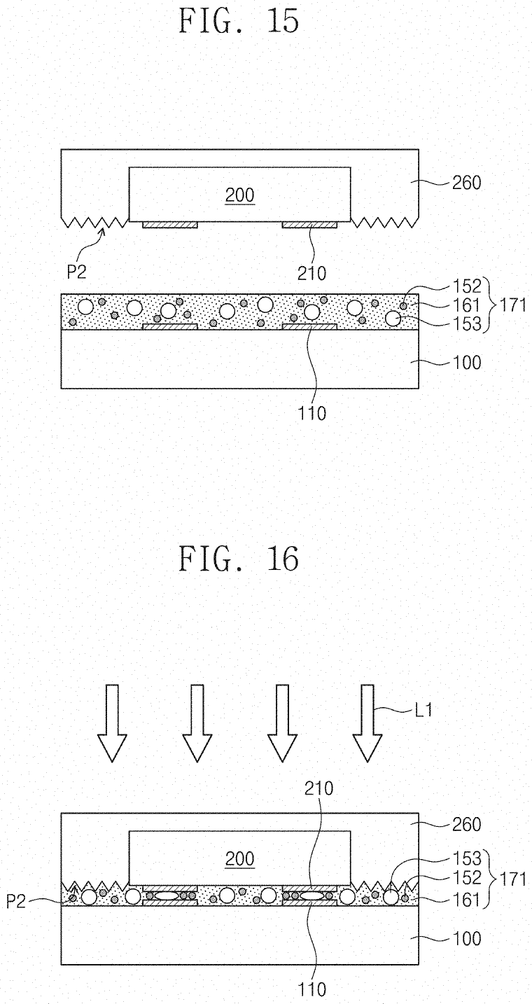

FIGS. 15 to 18 are cross-sectional views illustrating a method of manufacturing a semiconductor package using a composition for conductive adhesive according to an embodiment of the inventive concept. The same descriptions as provided above are omitted below.

Referring to FIG. 15, the substrate 100 may be provided. The substrate 100 may include the substrate pads 110 adjacent to the upper surface of the substrate 100. A conductive adhesive film 171 may be formed on at least one of the upper surface of the substrate 100 or the lower surface of the semiconductor chip 200. The conductive adhesive film 171 may cover the upper surface of the substrate 100 and the substrate pads 110. The conductive adhesive film 171 may include a composition 161 for conductive adhesive, conductive particles 152, and nonconductive particles 153. Forming the conductive adhesive film 171 may include applying a composition including the composition 161 for conductive adhesive, the conductive particles 152, and the nonconductive particles 153.

The semiconductor chip 200 may be provided on the substrate 100. The semiconductor chip 200 may include the chip pads 210 corresponding to the substrate pads 110. Providing the semiconductor chip 200 may include providing a mold 260 contacting one or more surfaces of the semiconductor chip 200. The mold 260 may cover the upper surface of the semiconductor chip 200 or the upper surface and sidewall thereof. The mold 260 may expose the lower surface of the semiconductor chip 200 and the chip pads 210. The lower surface of the mold 260 exposed by the semiconductor chip 200 may include mold protruding and recessed sections P2.

Referring to FIG. 16, the semiconductor chip 200 may be aligned so that each of the chip pads 210 is arranged on the corresponding substrate pad 110. Accordingly, the conductive particles 152 and the nonconductive particles 153 may be arranged between the chip pads 210 and the substrate pads 110. The semiconductor chip 200 may be arranged so that the lower surface of the semiconductor chip 200 covers a portion of an upper surface of the conductive adhesive film 171. The mold 260 may be arranged so that the lower surface of the mold 260 covers another portion of the upper surface of the conductive adhesive film 171.

A heating process L1 may be performed on at least one of the substrate 100, the semiconductor chip 200, or the conductive adhesive film 171. For example, the heating process may include at least one of infrared heating, resistance heating, arc heating, induction heating, dielectric heating, or electron beam heating. For example, the infrared heating may include a process of radiating infrared radiation (IR) laser.

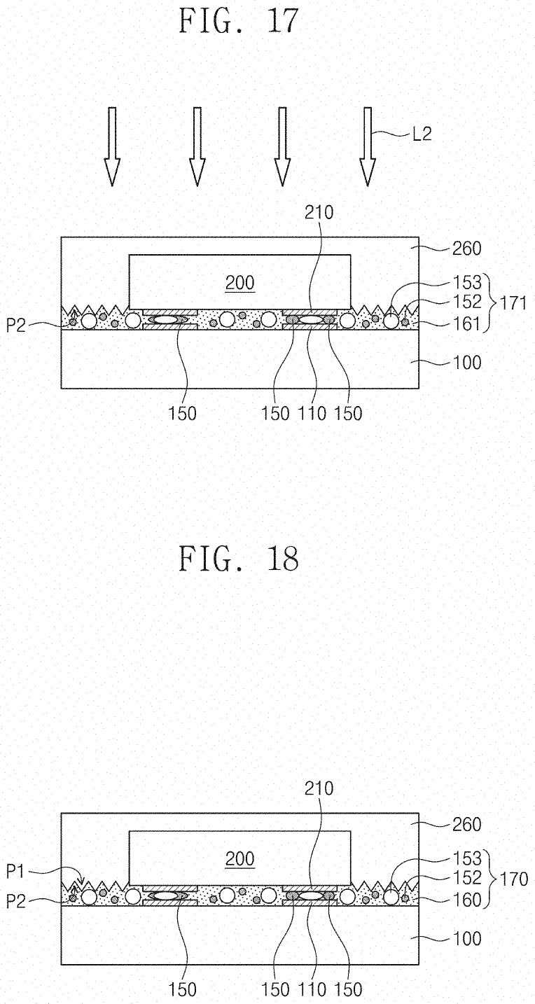

Referring to FIG. 17, the conductive particles 152 between the substrate pads 110 and the chip pads 210 may be fused and wet by the heating process L1, thereby forming the solder bonding portions 150. Accordingly, the substrate pads 110 and the chip pads 210 may be electrically connected by the solder bonding portions 150 between the substrate pads 110 and the chip pads 210. In some embodiments, a pressing process may be further performed on the semiconductor chip 200 for efficient fusing and wetting of the conductive particles 152. In detail, the heating process L1 may be performed during the pressing process in which the semiconductor chip 200 provided on the substrate 100 is pressed with a specific pressure.

A light radiation process L2 may be performed on at least one of the substrate 100, the semiconductor chip 200, or the conductive adhesive film 171. For example, the light radiation process L2 may include a process of radiating ultraviolet (UV) light. According to an embodiment of the inventive concept, an order in which the heating process L1 and the light radiation process L2 are performed may not be particularly limited. According to an embodiment of the inventive concept, the light radiation process L2 may be performed during the pressing process in which the semiconductor chip 200 provided on the substrate 100 is pressed with a specific pressure.

According to an embodiment of the inventive concept, it may be difficult for the lower surface of the mold 260 to directly contact the upper surface of the conductive adhesive film 171 when the mold 260 covers only the upper surface or a portion of the upper surface and sidewall of the semiconductor chip 200 unlike the illustrations of the FIGS. 15 to 18; however, in this case, the lower surface of the mold 260 may directly contact the upper surface of the conductive adhesive film 171 as the mold 260 is deformed due to the pressing process.

Referring to FIG. 18, the conductive adhesive cured product 170 may be formed by the light radiation process L2. Forming the conductive adhesive cured product 170 may include transferring a pattern of the mold protruding and recessed sections P2 of the lower surface of the mold 260 to the upper surface of the conductive adhesive film 171 and curing the conductive adhesive film 171. Accordingly, the protruding and recessed sections P1 may be formed on the upper surface of the conductive adhesive cured product 170 by the light radiation process L2.

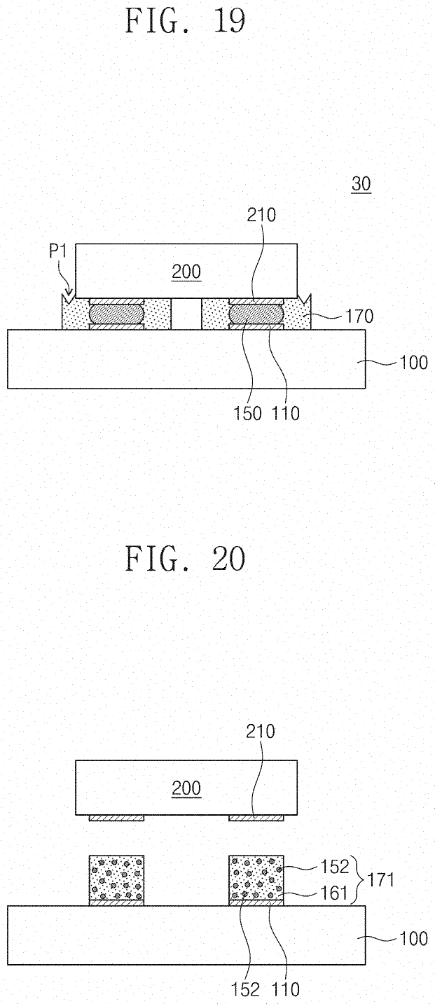

FIG. 19 is a cross-sectional view for describing a semiconductor package manufactured using a composition for conductive adhesive according to an embodiment of the inventive concept. The same descriptions as provided above are omitted below.

Referring to FIG. 19, a semiconductor package 30 may include the substrate 100, the semiconductor chip 200, the solder bonding portion 150, and the conductive adhesive cured product 170.

The substrate 100 may be provided. The substrate 100 may include the substrate pads 110 adjacent to the upper surface of the substrate 100. The semiconductor chip 200 may be provided on the substrate 100. The semiconductor chip 200 may include chip pads 210 corresponding to the substrate pads 110.

The solder bonding portions 150 may be arranged between the substrate 100 and the semiconductor chip 200. The substrate 100 and the semiconductor chip 200 may be electrically connected by the solder bonding portions 150. The solder bonding portions 150 may be arranged between the substrate pads 110 and the chip pads 210. Each of the substrate pads 110 may be electrically connected to a corresponding one among the chip pads 210 via a corresponding one among the solder bonding portions 150.

The conductive adhesive cured product 170 may be arranged on at least one of the upper surface of the substrate 100 or the lower surface of the semiconductor chip 200. The conductive adhesive cured product 170 may be arranged between the substrate 100 and the semiconductor chip 200. The conductive adhesive cured product 170 may be provided in plurality, and the conductive adhesive cured products 170 may be spaced apart laterally. Each of the conductive adhesive cured products 170 may seal the solder bonding portion 150 and may cover the substrate pad 110 and the chip pad 210. The conductive adhesive cured products 170 may cover a portion of the upper surface of the substrate 100, a portion of the lower surface of the semiconductor chip 200, and a portion of a side surface of the semiconductor chip 200. In some embodiments, the conductive adhesive cured product 170 may cover a lower sidewall of the semiconductor chip 200. An upper surface of the conductive adhesive cured product 170 may include protruding and recessed sections P1. In detail, the upper surface of the conductive adhesive cured product 170 exposed by the semiconductor chip 200 may include the protruding and recessed sections P1. The conductive adhesive cured product 170 may include a composition for conductive adhesive. The conductive adhesive cured product 170 may include a cured product of a composition for conductive adhesive. The composition for conductive adhesive may include a heterocyclic compound including at least one of an epoxy group or an oxetane group, a reductive curing agent including an amine group and a carboxyl group, and a photoinitiator. The descriptions provided above with reference to FIG. 1 may also apply to the heterocyclic compound, the reductive curing agent, and the photoinitiator.

The composition for conductive adhesive may further include at least one of an amine-based curing agent including an amine group, an acid anhydride-based curing agent including an acid anhydride group, or a reducing agent including a carboxyl group. The descriptions provided above with reference to FIG. 1 may also apply to the amine-based curing agent, the acid anhydride-based curing agent, and the reducing agent.

The composition for conductive adhesive may further include at least one of conductive particles, nonconductive particles, deforming agents, catalysts, latent curing agents, thermal-acid generators, sensitizers, chelating agents, dyes, carbon black, graphene, carbon nanotubes, fullerenes, or combinations thereof. The descriptions provided above with reference to FIG. 1 may also apply to the conductive particles.

Referring back to FIG. 11, the mold 260 may be removed.

FIGS. 20 to 22 are cross-sectional views illustrating a method of manufacturing a semiconductor package using a composition for conductive adhesive according to an embodiment of the inventive concept. The same descriptions as provided above are omitted below.

Referring to FIG. 20, the substrate 100 may be provided. The substrate 100 may include the substrate pads 110 adjacent to the upper surface of the substrate 100. Conductive adhesive films 171 that are spaced apart laterally may be formed on at least one of the upper surface of the substrate 100 or the lower surface of the semiconductor chip 200. The conductive adhesive films 171 may respectively cover upper surfaces of the substrate pads 110. Each of the conductive adhesive films 171 may include a composition 161 for conductive adhesive and conductive particles 152. Forming the conductive adhesive film 171 may include applying a composition including the composition 161 for conductive adhesive and the conductive particles 152.

The semiconductor chip 200 may be provided on the substrate 100. The semiconductor chip 200 may include the chip pads 210 corresponding to the substrate pads 110.

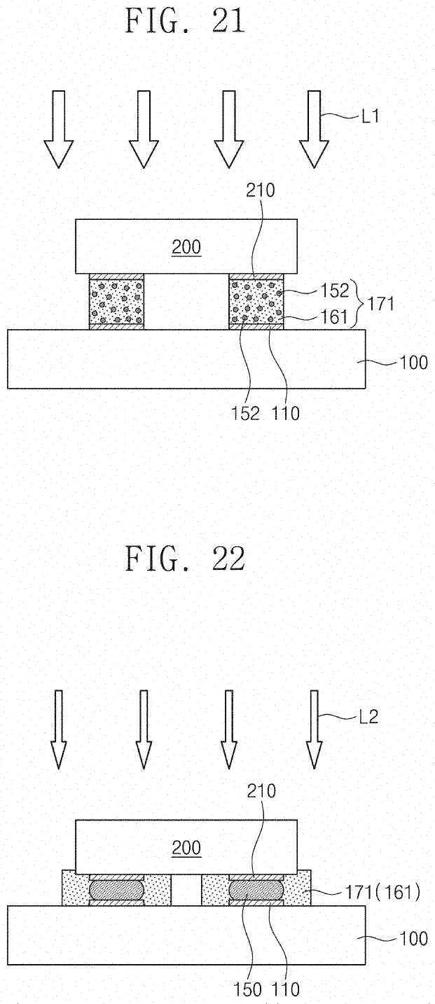

Referring to FIG. 21, the semiconductor chip 200 may be aligned so that each of the chip pads 210 is arranged on the corresponding substrate pad 110. Accordingly, each of the conductive adhesive films 171 may be arranged between the chip pad 210 and the substrate pad 110.

A heating process L1 may be performed on at least one of the substrate 100, the semiconductor chip 200, or the conductive adhesive film 171. For example, the heating process may include at least one of infrared heating, resistance heating, arc heating, induction heating, dielectric heating, or electron beam heating. For example, the infrared heating may include a process of radiating infrared radiation (IR) laser.

Referring to FIG. 22, the solder bonding portions 150 may be formed by the heating process L1, and the chip pads 210 and the substrate pads 110 may be electrically connected by the solder bonding portions 150. Forming the solder bonding portions 150 may include fusing and wetting the conductive particles 152 between the substrate pads 110 and the chip pads 210. Accordingly, the substrate pads 110 and the chip pads 210 may be electrically connected by the solder bonding portions 150 between the substrate pads 110 and the chip pads 210. In some embodiments, a pressing process may be further performed on the semiconductor chip 200 for efficient fusing and wetting of the conductive particles 152. In detail, the heating process L1 may be performed during the pressing process in which the semiconductor chip 200 provided on the substrate 100 is pressed with a specific pressure. Due to the heating process L1 and/or the pressing process, each of the conductive adhesive films 171 including the composition 161 for conductive adhesive may flow out so as to be arranged on a portion of the upper surface of the substrate 100, a portion of the lower surface of the semiconductor chip 200, and a portion of a side surface of the semiconductor chip 200. Accordingly, each of the conductive adhesive films 171 may seal the solder bonding portion 150 and may cover the substrate pad 110 and the chip pad 210.

A light radiation process L2 may be performed on at least one of the substrate 100, the semiconductor chip 200, or the conductive adhesive film 171. For example, the light radiation process L2 may include a process of radiating ultraviolet (UV) light. According to an embodiment of the inventive concept, an order in which the heating process L1 and the light radiation process L2 are performed may not be particularly limited. According to an embodiment of the inventive concept, the light radiation process L2 may be performed during the pressing process in which the semiconductor chip 200 provided on the substrate 100 is pressed with a specific pressure.

Referring back to FIG. 19, the conductive adhesive cured product 170 may be formed by the light radiation process L2. Forming the conductive adhesive cured product 170 may include forming the protruding and recessed sections P1 on the upper surface of the conductive adhesive cured product 170 while curing the conductive adhesive film 171.

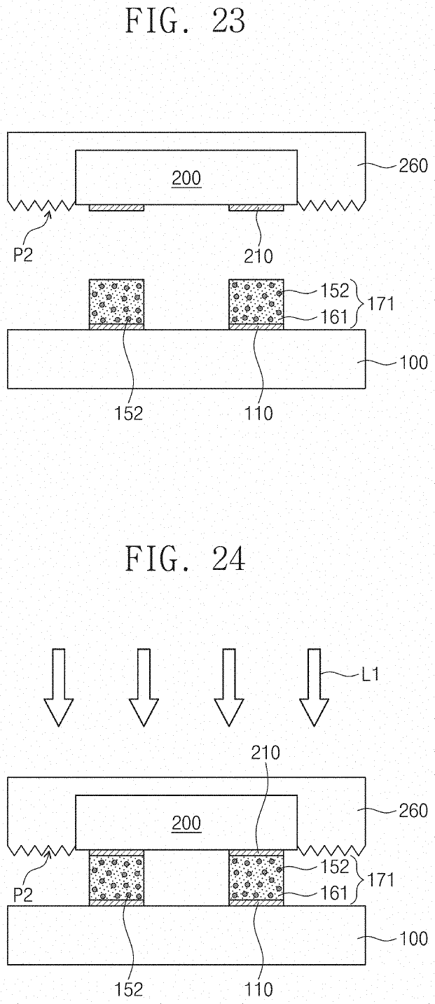

FIGS. 23 to 26 are cross-sectional views illustrating a method of manufacturing a semiconductor package using a composition for conductive adhesive according to an embodiment of the inventive concept. The same descriptions as provided above are omitted below.

Referring to FIG. 23, the substrate 100 may be provided. The substrate 100 may include the substrate pads 110 adjacent to the upper surface of the substrate 100. Conductive adhesive films 171 that are spaced apart laterally may be formed on at least one of the upper surface of the substrate 100 or the lower surface of the semiconductor chip 200. The conductive adhesive films 171 may respectively cover upper surfaces of the substrate pads 110. Each of the conductive adhesive films 171 may include a composition 161 for conductive adhesive and conductive particles 152. Forming the conductive adhesive film 171 may include applying a composition including the composition 161 for conductive adhesive and the conductive particles 152.

The semiconductor chip 200 may be provided on the substrate 100. The semiconductor chip 200 may include the chip pads 210 corresponding to the substrate pads 110. Providing the semiconductor chip 200 may include providing a mold 260 contacting one or more surfaces of the semiconductor chip 200. The mold 260 may cover the upper surface of the semiconductor chip 200 or the upper surface and sidewall thereof. The mold 260 may expose the lower surface of the semiconductor chip 200 and the chip pads 210. The lower surface of the mold 260 exposed by the semiconductor chip 200 may include mold protruding and recessed sections P2.

Referring to FIG. 24, the semiconductor chip 200 may be aligned so that each of the chip pads 210 is arranged on the corresponding substrate pad 110. Accordingly, each of the conductive adhesive films 171 may be arranged between the chip pad 210 and the substrate pad 110.

A heating process L1 may be performed on at least one of the substrate 100, the semiconductor chip 200, or the conductive adhesive film 171. For example, the heating process may include at least one of infrared heating, resistance heating, arc heating, induction heating, dielectric heating, or electron beam heating. For example, the infrared heating may include a process of radiating infrared radiation (IR) laser.

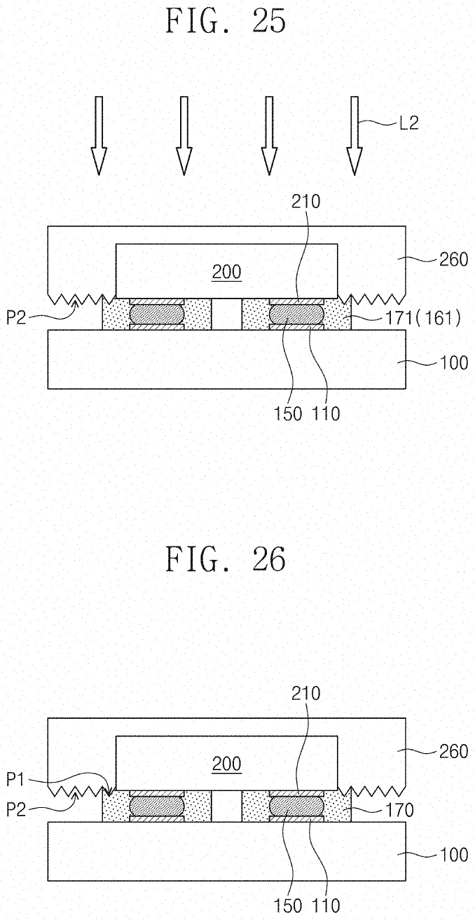

Referring to FIG. 25, the solder bonding portions 150 may be formed by the heating process L1, and the chip pads 210 and the substrate pads 110 may be electrically connected by the solder bonding portions 150. Forming the solder bonding portions 150 may include fusing and wetting the conductive particles 152 between the substrate pads 110 and the chip pads 210. Accordingly, the substrate pads 110 and the chip pads 210 may be electrically connected by the solder bonding portions 150 between the substrate pads 110 and the chip pads 210. In some embodiments, a pressing process may be further performed on the semiconductor chip 200 for efficient fusing and wetting of the conductive particles 152. In detail, the heating process L1 may be performed during the pressing process in which the semiconductor chip 200 provided on the substrate 100 is pressed with a specific pressure. Due to the heating process L1 and/or the pressing process, each of the conductive adhesive films 171 including the composition 161 for conductive adhesive may flow out so as to be arranged on a portion of the upper surface of the substrate 100, a portion of the lower surface of the semiconductor chip 200, and a portion of a side surface of the semiconductor chip 200. Accordingly, each of the conductive adhesive films 171 may seal the solder bonding portion 150 and may cover the substrate pad 110 and the chip pad 210.

A light radiation process L2 may be performed on at least one of the substrate 100, the semiconductor chip 200, or the conductive adhesive film 171. For example, the light may include ultraviolet (UV) light. According to an embodiment of the inventive concept, an order in which the heating process L1 and the light radiation process L2 are performed may not be particularly limited. According to an embodiment of the inventive concept, the light radiation process L2 may be performed during the pressing process in which the semiconductor chip 200 provided on the substrate 100 is pressed with a specific pressure.

According to an embodiment of the inventive concept, it may be difficult for the lower surface of the mold 260 to directly contact the upper surface of the conductive adhesive film 171 when the mold 260 covers only the upper surface or a portion of the upper surface and sidewall of the semiconductor chip 200 unlike the illustrations of the FIGS. 23 to 26; however, in this case, the lower surface of the mold 260 may directly contact the upper surface of the conductive adhesive film 171 as the mold 260 is deformed due to the pressing process.

Referring to FIG. 26, the conductive adhesive cured product 170 may be formed by the light radiation process L2. Forming the conductive adhesive cured product 170 may include transferring a pattern of the mold protruding and recessed sections P2 of the lower surface of the mold 260 to the upper surface of the conductive adhesive film 171 and curing the conductive adhesive film 171. Accordingly, the protruding and recessed sections P1 may be formed on the upper surface of the conductive adhesive cured product 170 by the light radiation process L2.

Referring back to FIG. 19, the mold 260 may be removed.

### EXAMPLES

Compositions for conductive adhesive were prepared using diglycidyl ether bisphenol A (DGEBA) as the heterocyclic compound, L-Lysine as the reductive curing agent, UVI-6976 as the photoinitiator, 4,4′-diaminodiphenylmethane (DDM) as the amine-based curing agent, tetrahydro phthalic anhydride (THPA) as the acid anhydride-based curing agent, and pimelic acid as the reducing agent. Example 1, Example 2, and Comparative Example 1 were prepared by adjusting parts by weight of components based on 100 parts by weight of diglycidyl ether bisphenol A (DGEBA) as shown in Table 1 below.

TABLE 1

| | | | Comparative |
|---|---|---|---|
| Components | Example 1 | Example 2 | Example 1 |
| DGEBA (Diglycidyl ether | 100.0 | 100.0 | 100 |
| bisphenol A) | | | |
| L-Lysine | 13.7 | 12.0 | — |
| UVI-6976 | 4.0 | 4.0 | 4.0 |
| DDM (4,4′- | | 3.0 | 11.0 |
| Diaminodiphenylmethane) | | | |
| THPA (Tetrahydro | | 10.0 | 37.0 |
| phthalic anhydride) | | | |
| Pimelic acid | | 4.8 | 16.0 |

### Experimental Example

Oxide film removal functionality, pot life, and post-light radiation surface tackiness of compositions for conductive adhesive prepared according to Example 1, Example 2, and Comparative Example 1 were evaluated as below.

### Experimental Example 1: Evaluation of Oxide Film Removal Functionality

The compositions for conductive adhesive prepared according to Example 1, Example 2, and Comparative Example 1 were applied onto a substrate that was surface treated with copper to a thickness of about 150 m, and 10 SAC305 (Sn-3.0Ag-0.5Cu) solder balls having a diameter of about 150 m were placed thereon. Thereafter, the compositions for conductive adhesive were heated from a room temperature to a temperature of about 240° C. at a heating rate of about 2° C./sec and maintained at a temperature of about 240° C. for about five seconds, and were cooled to a room temperature at a rate of about −2° C./sec. Total numbers of solder balls of which oxide films were removed and which were wet on the substrate among the 10 solder balls were measured, and the result is shown in Table 2 below.

### Experimental Example 2: Measurement of Pot Life

Initial viscosity of the compositions for conductive adhesive prepared according to Example 1, Example 2, and Comparative Example 1 was measured under a condition of about 50% RH and at a temperature of about 25° C. using a Brookfield viscometer (HBDV-II+P) according to ASTM D 2196. A holding time that had elapsed until the viscosity increased by at least 20% in comparison with the initial viscosity after holding the compositions for conductive adhesive under a condition of about 50% RH and at a temperature of about 25° C. was measured and determined as a pot life, and the result is shown in Table 2 below.

### Experimental Example 3: Evaluation of Post-Light Radiation Surface Tackiness

The compositions for conductive adhesive prepared according to Example 1, Example 2, and Comparative Example 1 were applied onto a glass substrate to a thickness of about 200 m under a condition of about 50% RH and at a temperature of about 25° C., and UV light (UVA, 1 J/cm²) was radiated thereto. Thereafter, the tackiness of the compositions was measured using a tackiness tester (TK-1S) according to JIS-Z-3284, and the result is shown in Table 2 below.

TABLE 2

| | Oxide film removal | | Post-light radiation |
|---|---|---|---|
| | functionality | Pot life | surface tackiness |
| | [count] | [Time] | [kPa] |
| Example 1 | 10 | >72 | 0 |
| Example 2 | 9 | >72 | 0 |
| Comparative | 5 | 18 | 0 |
| Example 1 | | | |

It may be confirmed from the result shown in Table 2 that a composition for conductive adhesive according to an embodiment of the inventive concept may be initiated by light and heat and have improved metal oxide film removal efficiency and pot life characteristic. In addition, it was confirmed that surface tackiness may be removed since the composition for conductive adhesive is cured by a light radiation process.

The composition for conductive adhesive of an embodiment of the inventive concept may be initiated by light and heat, and, thus, the curing characteristic of the composition for conductive adhesive may be improved, and metal oxide film removal efficiency and pot life characteristic may also be improved. Accordingly, bonding processes of various methods may be possible, in which heating process and light radiation are combined. In addition, a pattern may be formed on a surface of a cured product of the composition for conductive adhesive by a light radiation process, and a functionality may be imparted accordingly. Ultimately, the composition for conductive adhesive of an embodiment of the inventive concept may be applied in the fields of various electronic packages, such as display, signage, AR/VR display, camera module, sensor, semiconductor, power semiconductor, or electronic part.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A composition for conductive adhesive, comprising:
a heterocyclic compound containing oxygen, the heterocyclic compound including at least one of an epoxy group or oxetane group;
a reductive curing agent including an amine group and a carboxyl group; and
a photoinitiator,
wherein a mixture ratio of the heterocyclic compound and the reductive curing agent satisfies Conditional Expression 1 below:
0.5≤(b+c)/a≤1.5, a>0, b≥0, c>0 [Conditional Expression 1]
where ‘a’ denotes a mole number of a heterocycle in the heterocyclic compound, ‘b’ denotes a mole number of hydrogen bonded to a nitrogen atom of the amine group included in the reductive curing agent, and ‘c’ denotes a mole number of the carboxyl group.

2. The composition for conductive adhesive of claim 1, wherein the heterocyclic compound comprises at least one of bisphenol-A type epoxy resin, bisphenol-F type epoxy resin, novolac epoxy resin, hydrogenated bisphenol-A type epoxy resin, octylene oxide, p-butyl phenol glycidyl ether, butyl glycidyl ether, cresyl glycidyl ether, styrene oxide, allyl glycidyl ether, phenyl glycidyl ether, butadiene dioxide, divinylbenzene dioxide, diglycidyl ether, butanediol diglycidyl ether, limonene dioxide, vinylcyclohexene dioxide, diethylene glycol diglycidyl ether, 4-vinylcyclohexene dioxide, cyclohexene vinyl monoxide, (3,4-epoxycyclohexyl)methyl 3,4-epoxycyclohexylcarboxylate, 3,4-epoxycyclohexylmethyl methacrylate, 3,4-epoxycyclohexanecarboxylate, 2-(3,4-epoxycyclohexyl)-1,3-dioxolane, bis(3,4-epoxycyclohexylmethyl)adipate, 3-methyloxetane, 2-methyloxetane, 3-oxetanol, 2-methyleneoxetane, 3-methyl-3-hydroxymethyloxetane, 3-ethyl-3-hydroxymethyloxetane, 3,3-oxetanedimethanethiol, 2-ethylhexyloxetane, 4-(3-methyloxetan-3-yl)benzonitrile, N-(2,2-dimethylpropyl)-3-methyl-3-oxetanemethanamine, N-(1,2-dimethylbutyl)-3-methyl-3-oxetanemethanamine, xylene bis oxetane, 3-ethyl-3[{(3-ethyloxetan-3-yl)methoxy}methyl]oxetane, (3-ethyloxetan-3-yl)methyl methacrylate, 4-[(3-ethyloxetan-3-yl)methoxy]butan-1-ol, or combinations thereof.

3. The composition for conductive adhesive of claim 1, wherein the reductive curing agent comprises at least one of alpha(α)-amino acid, beta(β)-amino acid, gamma(γ)-amino acid, delta(δ)-amino acid, glycine, alanine, valine, leucine, isoleucine, lysine, arginine, histidine, aspartic acid, asparagine, glutamine, glutamic acid, phenylalanine, tyrosine, tryptophan, cysteine, methionine, serine, ornithine, 3-phenylserine, threonine, L-dopa, norleucine, penicillamine, sarcosine, proline, hydroxyproline, 3-hydroxyproline, 3,4-dihydroproline, pipecolic acid, β-alanine, 3-aminobutyric acid, isoserine, 3-aminoisobutyric acid, 3-amino-2-phenylpropionic acid, 3-amino-5-methylhexanoic acid, 3-amino-4-phenylbutyric acid, 3-amino-4-hydroxybutyric acid, 3-amino-4-hydroxypentanoic acid, 3-amino-4-methylpentanoic acid, 3-amino-3-phenylpropionic acid, pyrrolidine-3-carboxylic acid, γ-aminobutyric acid, 4-amino-3-hydroxybutyric acid, 3-pyrrolidine-2-yl-propionic acid, 3-aminocyclohexanecarboxylic acid, 4-guanidinobutyric acid, 4-aminobenzoic acid, 3-aminobenzoic acid, 2-aminobenzoic acid, 3,5-diaminobenzoic acid, 4-aminosalicylic acid, 5-aminosalicylic acid, 3-aminoisonicotinic acid, 4-aminonicotinic acid, 5-aminonicotinic acid, 2-aminonicotinic acid, 6-aminonicotinic acid, 2-aminoisonicotinic acid, 6-aminopicolinic acid, or combinations thereof.

4. The composition for conductive adhesive of claim 1, wherein the photoinitiator is included in an amount of about 0.1 to about 10 parts by weight based on 100 parts by weight of the heterocyclic compound.

5. The composition for conductive adhesive of claim 1, further comprising at least one of:
an amine-based curing agent including an amine group;
an acid anhydride-based curing agent including an acid anhydride group; or
a reducing agent including a carboxyl group,
wherein a mixture ratio of the amine-based curing agent, the acid anhydride-based curing agent, and the reducing agent satisfies Conditional Expression 2 below:
0.5≤(b+c+d+e+f)/a≤1.5, (b+c)≥(d+e+f), a>0, b≥0, c>0, d≥0, e≥0, f≥0, d+e+f≠0 [Conditional Expression 2]
where ‘a’ denotes a mole number of a heterocycle in the heterocyclic compound, ‘b’ denotes a mole number of hydrogen bonded to a nitrogen atom of the amine group included in the reductive curing agent, ‘c’ denotes a mole number of the carboxyl group included in the reductive curing agent, ‘d’ denotes a mole number of hydrogen bonded to a nitrogen atom of the amine group included in the amine-based curing agent, ‘e’ denotes a mole number of the acid anhydride group included in the acid anhydride-based curing agent, and ‘f’ denotes a mole number of the carboxyl group included in the reducing agent.

6. The composition for conductive adhesive of claim 5, wherein the amine-based curing agent comprises at least one of diethylenetriamine, triethylenediamine, triethylenetetramine, tetraethylenepentamine, diethylaminopropyleneamine, aminoethylpiperazine, menthane diamine, isophorone diamine, methaphenilene diamine, diaminodiphenylmethane, diaminodiphenylsulfone, 2-methyl-4-nitroaniline, dicyandiamide, 2-methylimidazole, 2-ethyl-4-methylimidazole, 2,4-dimethylimidazole, 2-phenylimidazole, 2-phenyl-4-methylimidazole, 1-cyanoethyl-2-undecylimidazolium trimellitate, epoxyimidazole adduct, or combinations thereof.

7. The composition for conductive adhesive of claim 5, wherein the acid anhydride-based curing agent comprises at least one of phthalic anhydride, trimellitic anhydride, pyromellitic dianhydride, benzophenonetetracarboxylic dianhydride, maleic anhydride, tetrahydrophthalic anhydride, methyl tetrahydrophthalic anhydride, endomethylene tetrahydrophthalic anhydride, methyl endomethylene tetrahydrophthalic anhydride, methyl butenyl tetrahydrophthalic anhydride, dodecenyl succinic anhydride, hexahydrophthalic anhydride, methylhexahydrophthalic anhydride, succinic anhydride, methylcyclohexene dicarboxylic anhydride, chlorendic anhydride, or combinations thereof.

8. The composition for conductive adhesive of claim 5, wherein the reducing agent comprises at least one of formic acid, acetic acid, propionic acid, butyric acid, valeric acid, caproic acid, caprylic acid, decanoic acid, lauric acid, myristic acid, palmitic acid, stearic acid, oleic acid, linoleic acid, alpha-linolenic acid, cyclohexanecarboxylic acid, phenylacetic acid, benzoic acid, chlorobenzoic acid, bromobenzoic acid, nitrobenzoic acid, phthalic acid, isophthalic acid, terephthalic acid, salicylic acid, hydroxybenzoic acid, anthranilic acid, aminobenzoic acid, methoxybenzoic acid, glutaric acid, maleic acid, azelaic acid, abietic acid, adipic acid, ascorbic acid, acrylic acid, citric acid, or combinations thereof.

9. The composition for conductive adhesive of claim 1, further comprising a conductive particle, wherein the conductive particle comprises at least one tin (Sn), copper (Cu), silver (Ag), bismuth (Bi), indium (In), lead (Pd), cadmium (Cd), antimony (Sb), gallium (Ga), arsenic (As), germanium (Ge), zinc (Zn), aluminum (Al), gold (Au), silicon (Si), nickel (Ni), phosphorus (P), or alloys selected from combinations thereof.

10. The composition for conductive adhesive of claim 9, wherein the conductive particle is included in an amount of about 1 vol % to about 60 vol % based on a total volume of the composition for conductive adhesive.

11. The composition for conductive adhesive of claim 1, further comprising a nonconductive particle, wherein the nonconductive particle comprises a polymer particle or an inorganic particle.

12. A semiconductor package comprising:
a substrate including a substrate pad adjacent to an upper surface thereof;
a semiconductor chip including a chip pad corresponding to the substrate pad;
solder bonding portions between the substrate and the semiconductor chip; and
a conductive adhesive cured product on at least one of the upper surface of the substrate or a lower surface of the semiconductor chip,
wherein the conductive adhesive cured product is a cured product of a composition for conductive adhesive,
wherein the composition for conductive adhesive comprises:
a heterocyclic compound containing oxygen, the heterocyclic compound including at least one of an epoxy group or oxetane group;
a reductive curing agent including an amine group and a carboxyl group; and
a photoinitiator.

13. The semiconductor package of claim 12, wherein an upper surface of the conductive adhesive cured product comprises protruding and recessed sections.

14. A method of manufacturing a semiconductor package, comprising:
providing a substrate including a substrate pad adjacent to an upper surface thereof;
providing a semiconductor chip on the substrate, the semiconductor chip including a chip pad corresponding to the substrate pad;
providing a conductive adhesive film on at least one of the upper surface of the substrate or a lower surface of the semiconductor chip, the conductive adhesive film including a composition for conductive adhesive;
electrically connecting the chip pad and the substrate pad by performing a heating process on at least one of the substrate, the semiconductor chip, or the conductive adhesive film; and
forming a conductive adhesive cured product by radiating light onto at least one of the substrate, the semiconductor chip, or the conductive adhesive film,
wherein the forming of the conductive adhesive cured product comprises forming protruding and recessed sections on an upper surface of the conductive adhesive cured product,
wherein the composition for conductive adhesive comprises:
a heterocyclic compound containing oxygen, the heterocyclic compound including at least one of an epoxy group or oxetane group;
a reductive curing agent including an amine group and a carboxyl group; and
a photoinitiator.

15. The method of claim 14,
wherein the heating process comprises a process of radiating infrared radiation (IR) laser, and
wherein the light comprises ultraviolet (UV) light.

16. The method of claim 14,
wherein the providing of the semiconductor chip comprises providing a mold contacting one or more surfaces of the semiconductor chip,
wherein a lower surface of the mold exposed by the semiconductor chip comprises mold protruding and recessed sections.

17. The method of claim 16, wherein the forming of the protruding and recessed sections on the upper surface of the conductive adhesive cured product comprises transferring a pattern of the mold protruding and recessed sections of the lower surface of the mold to the upper surface of the conductive adhesive cured product.

18. The method of claim 14,
wherein the composition for conductive adhesive further comprises conductive particles,
wherein the conductive particles between the substrate pad and the chip pad are fused and wet by the heating process, thereby forming a solder bonding portion.

19. The method of claim 14,
wherein each of the conductive adhesive film, the substrate pad, and the chip pad is provided in plurality,
wherein the conductive adhesive films are spaced apart laterally, and each of the conductive adhesive films covers an upper surface of each of the substrate pads or a lower surface of each of the chip pads.

20. The method of claim 19,
wherein each of the conductive adhesive films is arranged between the chip pad and the substrate pad,
wherein each of the conductive adhesive films flows out so as to be arranged on a portion of the upper surface of the substrate, a portion of the lower surface of the semiconductor chip, and a portion of a side surface of the semiconductor chip due to the heating process.
